(19) United States
(12) Patent Application Publication
(10) Pub. No.: US 2026/0101663 A1
(43) Pub. Date: Apr. 9, 2026

(54) DISPLAY DEVICE, OPTICAL DEVICE, ELECTRONIC DEVICE AND METHOD FOR FABRICATING DISPLAY DEVICE

(71) Applicant: Samsung Display Co., Ltd., Yongin-si (KR)

(72) Inventors: Myeong Hun SONG, Yongin-si (KR); Gun Shik KIM, Yongin-si (KR); Sang Yeol KIM, Yongin-si (KR); Jin Yong KIM, Yongin-si (KR); Bong Chun PARK, Yongin-si (KR); Seung Woo SEO, Yongin-si (KR); Ji Hyun HAM, Yongin-si (KR)

(21) Appl. No.: 19/215,065

(22) Filed: May 21, 2025

(30) Foreign Application Priority Data
Oct. 7, 2024 (KR) 10-2024-0135381

(51) Int. Cl. H10K 59/80; H10K 59/122

(52) U.S. Cl. CPC H10K 59/873; H10K 59/122

(57) ABSTRACT

A display device, an optical device, an electronic device and a method for fabricating the display device are provided. The display device includes a substrate, a first electrode on the substrate, a pixel-defining film on the first electrode, a light-emitting stack on the first electrode and the pixel-defining film, a second electrode on the light-emitting stack; and an encapsulation layer on the second electrode, wherein the encapsulating layer includes a plurality of sub-encapsulation layers and at least two ends of the plurality of sub-encapsulation layers are aligned along one direction.

### CROSS-REFERENCE TO RELATED APPLICATION

The present application claims priority to and the benefit of Korean Patent Application No. 10-2024-0135381, filed on Oct. 7, 2024, in the Korean Intellectual Property Office, the entire content of which is incorporated herein by reference.

### BACKGROUND

### 1. Field

Embodiments of the present disclosure relate to a display device, and for example, to a display device, an optical device including the display device, an electronic device including the display device, and a method for fabricating the display device, which can reduce fabrication costs and improve reliability.

### 2. Description of the Related Art

A head-mounted display (HMD) is an image display device that is worn on a user's head, in the form of glasses or a helmet, to form a focus at a close distance in front of the user's eyes. The head mounted display may implement virtual reality (VR) or augmented reality (AR).

Head-mounted displays magnify an image displayed on a small display device by using a plurality of lenses, and displays the magnified image. Therefore, it is desirable that the display device used in the head-mounted display provides high-resolution images, for example, images with a resolution of 3000 PPI (Pixels Per Inch) or higher. To this end, an organic light-emitting diode on silicon (OLEDoS), which is a high-resolution small organic light-emitting display device, may be used as the display device applied to the head-mounted display. The OLEDoS is an image display device in which an organic light-emitting diode (OLED) is arranged on a semiconductor wafer substrate on which a complementary metal oxide semiconductor (CMOS) is arranged.

The above information disclosed in this Background section is intended to enhance understanding of the background of the disclosure and may contain information that does not constitute prior art

### SUMMARY

Aspects of embodiments of the present disclosure are directed to a display device, an optical device including the display device, an electronic device including the display device, and a method for fabricating the display device, which can reduce fabrication costs and improve reliability.

Aspects of embodiments of the present disclosure are directed to a display device in which an encapsulation layer is patterned together with a pad region in the process of exposing the pad region, so that the number of masks may be reduced, thereby reducing fabrication costs.

Additional aspects will be set forth in part in the description which follows and, in part, will be apparent from the description, or may be learned by practice of the presented embodiments of the disclosure.

According to one or more embodiments of the present disclosure, a display device includes: a substrate; a first electrode on the substrate; a pixel-defining film on the first electrode; a light-emitting stack on the first electrode and the pixel-defining film; a second electrode on the light-emitting stack; and an encapsulation layer on the second electrode, wherein the encapsulating layer includes a plurality of sub-encapsulation layers, and at least two ends of the plurality of sub-encapsulation layers are arranged (e.g., aligned) along one direction.

According to one or more embodiments of the present disclosure, an optical device includes: a display device; and an optical path changing member on the display device, wherein the display device includes: a substrate; a first electrode on the substrate; a pixel-defining film on the first electrode; a light-emitting stack on the first electrode and the pixel-defining film; a second electrode on the light-emitting stack; and an encapsulation layer on the second electrode, wherein the encapsulating layer includes a plurality of sub-encapsulation layers, and at least two ends of the plurality of sub-encapsulation layers are arranged (e.g., aligned) along one direction.

According to one or more embodiments of the present disclosure, an electronic device includes: a display device including a screen, wherein the display device includes: a substrate; a first electrode on the substrate; a pixel-defining film on the first electrode; a light-emitting stack on the first electrode and the pixel-defining film; a second electrode on the light-emitting stack; and an encapsulation layer on the second electrode, wherein the encapsulating layer includes a plurality of sub-encapsulation layers, and at least two ends of the plurality of sub-encapsulation layers are arranged (e.g., aligned) along one direction.

Further, according to one or more embodiments of the present disclosure, a method for fabricating a display device includes: forming a first electrode on a substrate; forming a pixel-defining film on the first electrode; forming a light-emitting stack on the first electrode; forming a second electrode on the light-emitting stack; forming a first sub-encapsulation layer on an entire surface of the second electrode; forming a second sub-encapsulation layer on the first sub-encapsulation layer using a first mask; forming a third sub-encapsulation layer on the first sub-encapsulation layer and the second sub-encapsulation layer; forming a fourth sub-encapsulation layer on an entire surface of the third sub-encapsulation layer; and patterning the first sub-encapsulation layer, the third sub-encapsulation layer, and the fourth sub-encapsulation layer using a second mask, while exposing a metal layer of a pad of the substrate.

According to the display device, the optical device, the electronic device and the method for fabricating the display device of one or more embodiments of the present disclosure, the fabrication cost of the display device may be reduced, and the reliability of the display device may be improved. The reduction in fabrication cost may be achieved through innovative design and manufacturing processes that minimize or reduce the number of masks required during encapsulation layer patterning. By integrating the encapsulation layer patterning with the pad region exposure process, the number of photolithography steps (e.g., acts tor tasks) is decreased, leading to lower material and labor costs. Additionally, the use of fewer masks reduces alignment errors and defects, enhancing the overall yield and quality of the display devices. The reliability is further improved by using advanced materials and precise fabrication techniques, providing robust protection against environmental factors.

The effects/aspects of the present disclosure are not limited to the above-described effects/aspects and other effects/aspects which are not described herein will become apparent to those skilled in the art from the following description.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is an exploded perspective view showing a display device according to one or more embodiments of the present disclosure;

FIG. 2 is a block diagram illustrating a display device according to one or more embodiments of the present disclosure;

FIG. 3 is an equivalent circuit diagram of a first sub-pixel according to one or more embodiments of the present disclosure;

FIG. 4 is a layout diagram illustrating a display panel according to one or more embodiments of the present disclosure;

FIGS. 5 and 6 are each a layout diagram illustrating a portion of the display area of FIG. 4, according to one or more embodiments of the present disclosure;

FIG. 7 is a cross-sectional view of a display panel taken along the line I1-I1′ of FIG. 5, according to one or more embodiments of the present disclosure;

FIG. 8 is an enlarged cross-sectional view showing the area A1 of FIG. 7, according to one or more embodiments of the present disclosure;

FIG. 9 is a layout diagram illustrating a first pad of the first pad portion of FIG. 4, according to one or more embodiments of the present disclosure;

FIG. 10 is a cross-sectional view taken along the line B-B′ of FIG. 9, according to one or more embodiments of the present disclosure;

FIG. 11 is a cross-sectional view of a portion of a display panel taken along the line E-E′ of FIG. 4, according to one or more embodiments of the present disclosure;

FIG. 12 is a cross-sectional view of a portion of a display panel taken along the line F-F′ of FIG. 4, according to one or more embodiments of the present disclosure;

FIG. 13 is an enlarged cross-sectional view of the area A2 of FIG. 11, according to one or more embodiments of the present disclosure;

FIG. 14 - 28 are cross-sectional views illustrating a method for fabricating a display device according to one or more embodiments of the present disclosure (FIGS. 14, 16, 18, 19, 21, 22, 23, 25, and 27 are each a cross-sectional view taken along the line I1-I1′ of FIG. 5 during a process of manufacturing, according to one or more embodiments of the present disclosure, and FIGS. 15, 17, 20, 24, 26 and 28 are each a cross-sectional view taken along the line B-B′ of FIG. 9 during a process of manufacturing, according to one or more embodiments of the present disclosure);

FIG. 29 is a cross-sectional view of a display device taken along the line E-E′ of FIG. 4, according to one or more embodiments of the present disclosure;

FIG. 30 is a perspective view illustrating a head-mounted display according to one or more embodiments of the present disclosure;

FIG. 31 is an exploded perspective view illustrating the head-mounted display of FIG. 30, according to one or more embodiments of the present disclosure; and

FIG. 32 is a perspective view illustrating a head-mounted display according to one or more embodiments of the present disclosure.

FIG. 33 is a block diagram of an electronic device according to one or more embodiments of the present disclosure.

FIGS. 34, 35 and 36 are schematic perspective diagrams of electronic devices according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art.

Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided. In the drawings, the relative sizes, including the thicknesses, of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

Features of various embodiments of the present disclosure may be combined partially or totally. As will be clearly appreciated by those skilled in the art, technically various interactions and operations are possible. Various embodiments can be practiced individually or in combination.

Hereinafter, specific embodiments will be described with reference to the accompanying drawings.

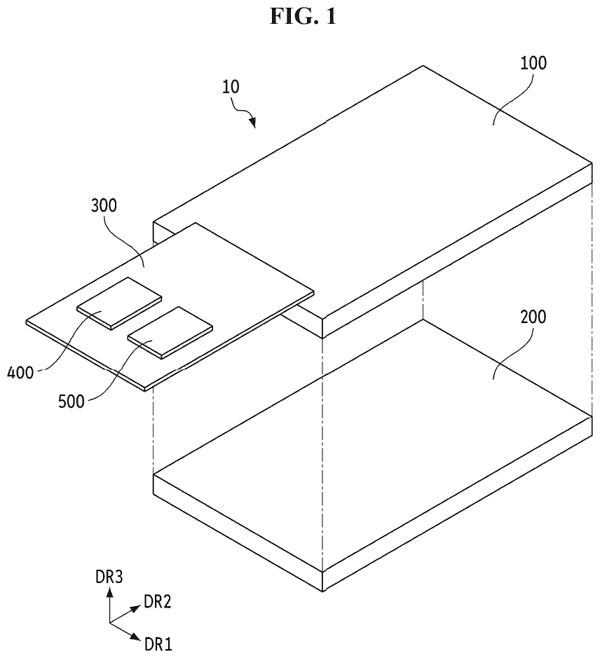

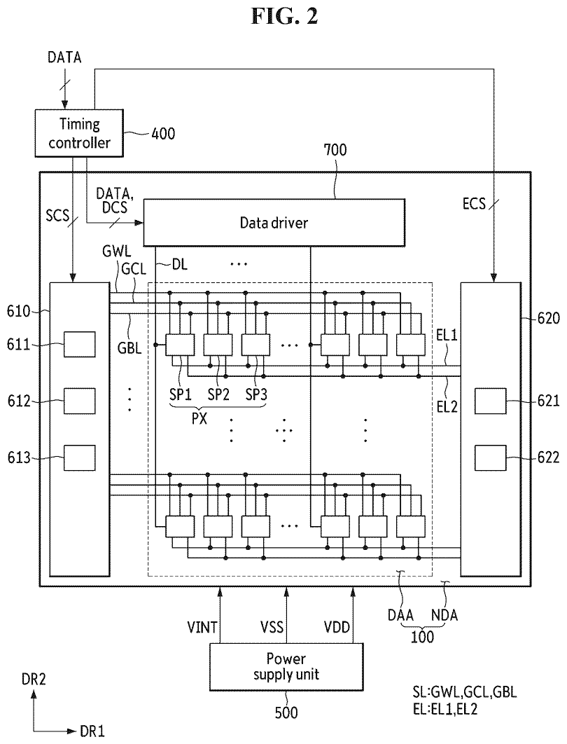

FIG. 1 is an exploded perspective view showing a display device according to one or more embodiments. FIG. 2 is a block diagram illustrating a display device according to one or more embodiments of the present disclosure.

Referring to FIGS. 1 and 2, a display device 10 according to one or more embodiments is a device for displaying a moving image and/or a still image. The display device 10 according to one or more embodiments may be applied to a portable electronic device such as a mobile phone, a smartphone, a tablet personal computer, a mobile communication terminal, an electronic organizer, an electronic book, a portable multimedia player (PMP), a navigation system, an ultra-mobile PC (UMPC) and/or the like. For example, the display device 10 according to one or more embodiments may be applied as a display unit of a television, a laptop, a monitor, a billboard, or an Internet-of-Things (IoT) terminal. In one or more embodiments, the display device 10 according to one or more embodiments may be applied to a smart watch, a watch phone, a head mounted display (HMD) for implementing virtual reality and/or augmented reality, and/or the like.

The display device 10 according to one or more embodiments includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1 (e.g., two short sides in a first direction DR1 and two long sides in a second direction DR2 to provide the four sides of a quadrilateral). In the display panel 100, a corner where a short side in the first direction DR1 and a long side in the second direction DR2 meet may be right-angled or rounded with a set or predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 2.

The plurality of pixels PX may be arranged in the display area DAA. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

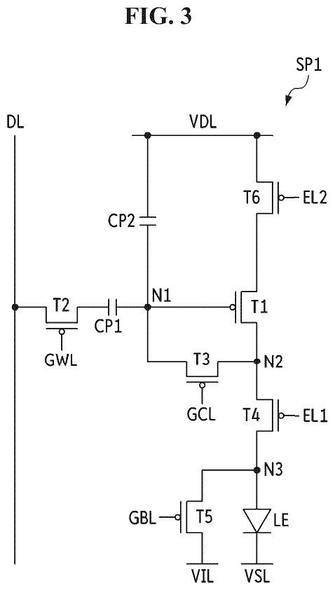

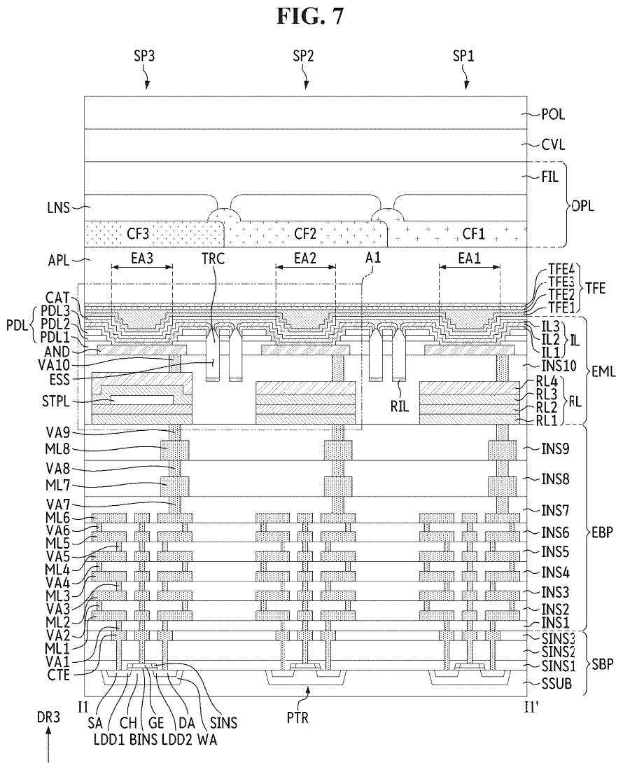

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and arranged on a semiconductor substrate SSUB (see, e.g., FIG. 7). For example, the plurality of pixel transistors of the data driver 700 may be formed of complementary metal oxide semiconductor (CMOS), but the present disclosure is not limited thereto.

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. For example, each sub-pixel SP1, SP2, and SP3 in the display area DAA may be connected to a corresponding write scan line GWL, control scan line GCL, bias scan line GBL, first emission control line EL1, second emission control line EL2 and data line DL. Each of the plurality of sub-pixels SP1, SP2, and SP3 may receive a data voltage from the data line DL in response to a write scan signal from the write scan line GWL, and may emit light from the light-emitting element according to the data voltage.

The scan driver 610, the emission driver 620, and the data driver 700 may be arranged in the non-display area NDA.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see, e.g., FIG. 7) through a semiconductor process. For example, the plurality of scan transistors and the plurality of light-emitting transistors may be formed of CMOS, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see, e.g., FIG. 7) through a semiconductor process. For example, the plurality of data transistors may be formed of CMOS, but the present disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to data lines DL. In such embodiments, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be arranged on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

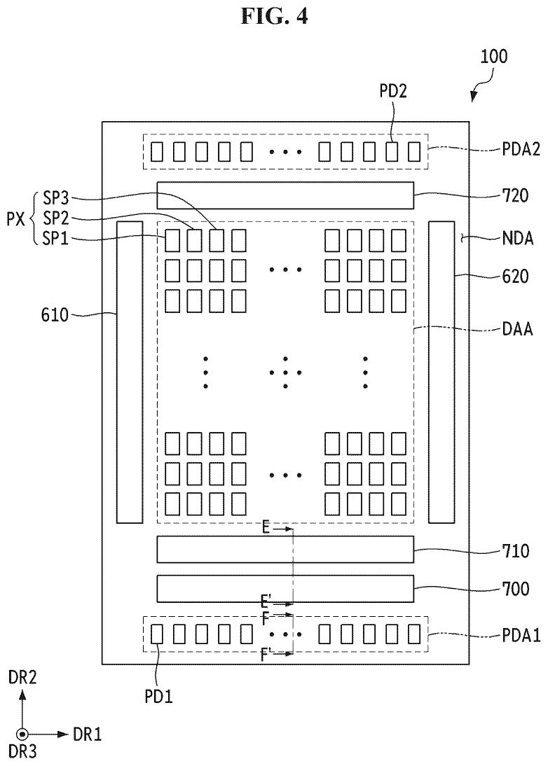

The circuit board 300 may be electrically connected to a plurality of first pads PD1 (see, e.g., FIG. 4) of a first pad portion PDA1 (see, e.g., FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In such embodiments, one end of the circuit board 300 may be arranged on the rear surface of the display panel 100 and/or the rear surface of the heat dissipation layer 200. The other end of the circuit board 300 may be connected to the plurality of first pads PD1 (see, e.g., FIG. 4) of the first pad portion PDA1 (see, e.g., FIG. 4) of the display panel 100 by using a conductive adhesive member. One end of the circuit board 300 may be an opposite end relative to the other end of the circuit board 300.

The timing control circuit 400 may receive digital video data and timing signals inputted from the outside (e.g., outside the display panel 100 and/or the display device 10). The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described in more detail later in conjunction with FIG. 3.

Each of the timing control circuit 400 and the power supply circuit 500 may be formed as an integrated circuit (IC) and attached to one surface of the circuit board 300. In such embodiments, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be arranged in the non-display area NDA of the display panel 100, similarly to the scan driver 610, the emission driver 620, and the data driver 700. In such embodiments, the timing control circuit 400 may include a plurality of timing transistors, and each power supply circuit 500 may include a plurality of power transistors. The plurality of timing transistors and the plurality of power transistors may be formed on the semiconductor substrate SSUB (see, e.g., FIG. 7) through a semiconductor process. For example, the plurality of timing transistors and the plurality of power transistors may be formed of CMOS, but the present disclosure is not limited thereto. Each of the timing control circuit 400 and the power supply circuit 500 may be arranged between the data driver 700 and the first pad portion PDA1 (see, e.g., FIG. 4).

FIG. 3 is an equivalent circuit diagram of a first sub-pixel according to one or more embodiments of the present disclosure. While one first subpixel SP1 is discussed with respect to FIG. 3, the configuration of the circuit for the remaining first, second and third pixels SP1, SP2, and SP3 throughout in the display area DAA may be similar to or the same as discussed with respect to FIG. 3.

Referring to FIG. 3, the first sub-pixel SP1 may be connected to a write scan line GWL, a control scan line GCL, a bias scan line GBL, a first emission control line EL1, a second emission control line EL2, and a data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. In such embodiments, the first driving voltage VSS may be lower than the third driving voltage VINT. The second driving voltage VDD may be higher than the third driving voltage VINT.

The first sub-pixel SP1 includes a plurality of transistors T1 to T6, a light-emitting element LE, a first capacitor CP1, and a second capacitor CP2.

The light-emitting element LE is to emit light in response to a driving current flowing through the channel of the first transistor T1. The emission amount of the light-emitting element LE may be proportional to the driving current. The light-emitting element LE may be arranged between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer arranged between the first electrode and the second electrode, but the present disclosure is not limited thereto. For example, the light-emitting element LE may be an inorganic light-emitting element including a first electrode, a second electrode, and an inorganic semiconductor arranged between the first electrode and the second electrode, in which case the light-emitting element LE may be a micro light-emitting diode.

The first transistor T1 may be a driving transistor that controls a source-drain current (hereinafter referred to as “driving current”) flowing between the source electrode and the drain electrode thereof according to a voltage applied to the gate electrode thereof. The first transistor T1 includes a gate electrode connected to a first node N1, a source electrode connected to the drain electrode of a sixth transistor T6, and a drain electrode connected to a second node N2.

A second transistor T2 may be arranged between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be arranged between the first node N1 and the second node N2. The third transistor T3 is turned on by the write control signal of the write control line GCL to connect the first node N1 to the second node N2. For this reason, if (e.g., when) the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

A fifth transistor T5 may be arranged between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 includes a gate electrode connected to the bias scan line GBL, a source electrode connected to the third node N3, and a drain electrode connected to the third driving voltage line VIL.

The sixth transistor T6 may be arranged between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1.

The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and another electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and another electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type (kind) MOSFET, but the present disclosure is not limited thereto. Each of the first to sixth transistors T1 to T6 may be an N-type (kind) MOSFET. In one or more embodiments, some of the first to sixth transistors T1 to T6 may be P-type (kind) MOSFETs, and each of the remaining transistors may be an N-type (kind) MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram of a display panel according to one or more embodiments of the present disclosure.

Referring to FIG. 4, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be arranged on the first side of the display area DAA, and the emission driver 620 may be arranged on the second side of the display area DAA. For example, the scan driver 610 may be arranged on one side of the display area DAA in the first direction DR1, and the emission driver 620 may be arranged on the other side of the display area DAA in the first direction DR1. For example, the scan driver 610 may be arranged on the left side of the display area DAA, and the emission driver 620 may be arranged on the right side of the display area DAA. However, the present disclosure is not limited thereto, and each of the scan driver 610 and the emission driver 620 may be arranged on either of the first side and/or the second side of the display area DAA.

The first pad portion PDA1 may include the plurality of first pads PD1 connected to pads or bumps of the circuit board 300 through a conductive adhesive member. The first pad portion PDA1 may be arranged on the third side of the display area DAA. For example, the first pad portion PDA1 may be arranged on one side of the display area DAA in the second direction DR2. The first pad portion PDA1 may be arranged outside the data driver 700 in the second direction DR2. For example, the first pad portion PDA1 may be arranged closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The second pad portion PDA2 may be arranged on the fourth side of the display area DAA. For example, the second pad portion PDA2 may be arranged on the other side of the display area DAA in the second direction DR2 relative to the first pad portion PDA1. The second pad portion PDA2 may be arranged outside the second distribution circuit 720 in the second direction DR2. For example, the second pad portion PDA2 may be arranged closer to the edge of the display panel 100 than the second distribution circuit 720.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to P (P is a positive integer of 2 or more) data lines DL, and as a result, the number of first pads PD1 may be reduced, as each first pad PD1 may distribute two or more data voltages to two or more respective data lines DL, thus reducing the number of first pads PD1 relative to data lines DL. The first distribution circuit 710 may be arranged on the third side of the display area DAA of the display panel 100. For example, the first distribution circuit 710 may be arranged on one side of the display area DAA in the second direction DR2. For example, the first distribution circuit 710 may be arranged on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be arranged on the fourth side of the display area DAA of the display panel 100. For example, the second distribution circuit 720 may be arranged on the other side of the display area DAA in the second direction DR2 relative to the first distribution circuit 710. For example, the second distribution circuit 720 may be arranged on the upper side of the display area DAA.

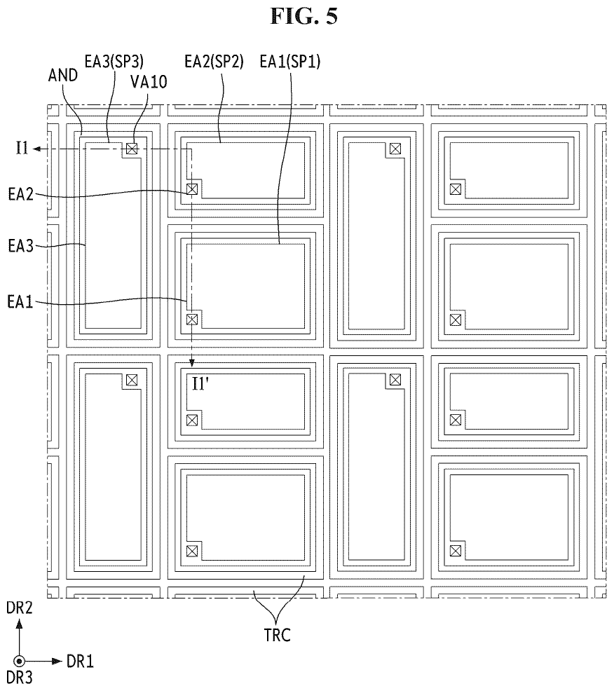

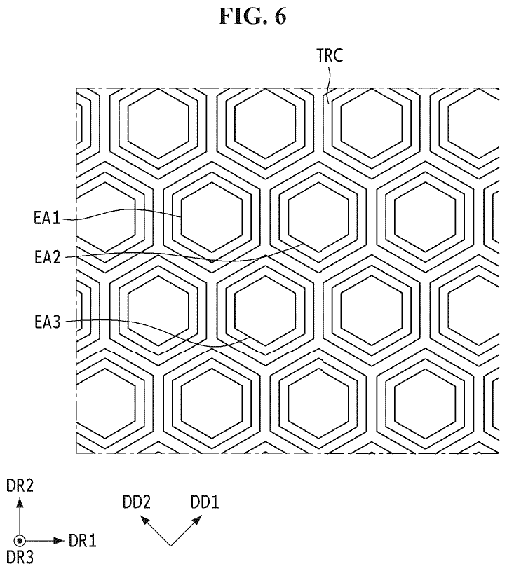

FIGS. 5 and 6 are each a layout diagram illustrating a portion of the display area of FIG. 4, according to one or more embodiments of the present disclosure.

Referring to FIGS. 5 and 6, each of the pixels PX may include a first emission area EA1 that is an emission area of the first sub-pixel SP1, a second emission area EA2 that is an emission area of the second sub-pixel SP2, and a third emission area EA3 that is an emission area of the third sub-pixel SP3.

Each of the first emission area EA1, the second emission area EA2, and the third emission area EA3 may have a polygonal, circular, elliptical, or atypical (e.g., non-geometric) shape in a plan view.

As shown, for example, in FIG. 5, the maximum length of the third emission area EA3 in the first direction DR1 may be less than each of the maximum length of the second emission area EA2 in the first direction DR1 and the maximum length of the first emission area EA1 in the first direction DR1. The maximum length of the second emission area EA2 in the first direction DR1 and the maximum length of the first emission area EA1 in the first direction DR1 may be substantially the same.

The maximum length of the third emission area EA3 in the second direction DR2 may be greater than each of the maximum length of the second emission area EA2 in the second direction DR2 and the maximum length of the first emission area EA1 in the second direction DR2. The maximum length of the second emission area EA2 in the second direction DR2 may be less than the maximum length of the first emission area EA1 in the second direction DR2. The maximum length of the first emission area EA1 in the second direction DR2 may be greater than the maximum length of the second emission area EA2 in the second direction DR2.

As shown, for example, in FIG. 6, the first emission area EA1, the second emission area EA2, and the third emission area EA3 may have, in plan view, a hexagonal shape formed of six straight lines, but the present disclosure is not limited thereto. The first emission area EA1, the second emission area EA2, and the third emission area EA3 may have a polygonal shape other than a hexagon, for example, they may have a circular shape, an elliptical shape, or an atypical shape in a plan view.

As shown in FIG. 5, in each of the plurality of pixels PX, the third emission area EA3 and the second emission area EA2 may be adjacent to each other in the first direction DR1. Further, the first emission area EA1 and the third emission area EA3 may be adjacent to each other in the first direction DR1. In one or more embodiments, the second emission area EA2 and the first emission area EA1 may be adjacent to each other in the second direction DR2. The area of the first emission area EA1, the area of the second emission area EA2, and the area of the third emission area EA3 may be different.

In one or more embodiments, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction normal (e.g., perpendicular) to the first diagonal direction DD1.

The first emission area EA1 may be to emit light of a first color, the second emission area EA2 may be to emit light of a second color, and the third emission area EA3 may be to emit light of a third color. Here, the first color light may be light of a red wavelength band, the second color light may be light of a green wavelength band, and the third color light may be light of a blue wavelength band. For example, the blue wavelength band may be a wavelength band of light whose main peak wavelength is in the range of approximately 370 nm to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

As shown in FIGS. 5 and 6, each of the plurality of pixels PX may include three emission areas EA1, EA2, and EA3, but the present disclosure is not limited thereto. For example, each of the plurality of pixels PX may include four emission areas.

In one or more embodiments, the layout of the emission areas of the plurality of pixels PX is not limited to those illustrated in FIGS. 5 and 6. For example, the emission areas of the plurality of pixels PX may be arranged in a stripe structure in which the emission areas are alternately arranged in the first direction DR1, a PENTILE® structure (for example, an RGBG matrix, an RGBG structure, or RGBG matrix structure), a diamond shape (DIAMOND PIXEL®) (e.g., a display (e.g., an OLED display) containing red, blue, and green (RGB) light emitting regions arranged in the shape of diamonds), or a hexagonal structure in which the emission areas having, in plan view, a hexagonal shape are arranged as shown in FIG. 6. PENTILE® and DIAMOND PIXEL® are duly registered trademarks of Samsung Display Co., Ltd.

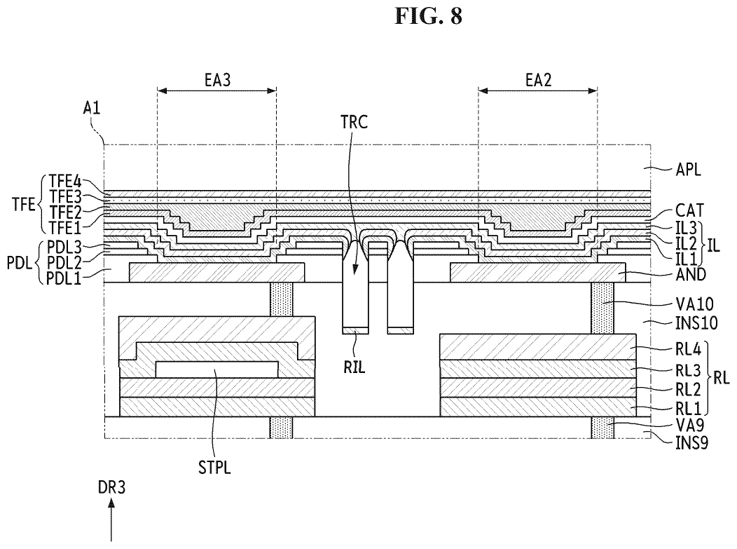

FIG. 7 is a cross-sectional view of a display panel taken along the line I1-I1′ of FIG. 5, according to one or more embodiments of the present disclosure. FIG. 8 is a cross-sectional view showing the area A1 of FIG. 7, according to one or more embodiments of the present disclosure.

Referring to FIGS. 7 and 8, the display panel 100 may include a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type (kind) impurity. A plurality of well regions WA may be arranged on the top surface of the semiconductor substrate SSUB. The plurality of well regions WA may be regions doped with a second type (kind) impurity. The second type (kind) impurity may be different from the aforementioned first type (kind) impurity. For example, if (e.g., when) the first type (kind) impurity is a p-type (kind) impurity, the second type (kind) impurity may be an n-type (kind) impurity. Alternatively, in one or more embodiments, if (e.g., when) the first type (kind) impurity is an n-type (kind) impurity, the second type (kind) impurity may be a p-type (kind) impurity.

Each of the plurality of well regions WA includes a source region SA corresponding to the source electrode of the pixel transistor PTR, a drain region DA corresponding to the drain electrode thereof, and a channel region CH arranged between the source region SA and the drain region DA.

A lower insulating layer BINS may be arranged between a gate electrode GE and the well region WA. A side insulating layer SINS may be arranged on the side surface of the gate electrode GE (e.g., on sides surfaces of the gate electrode GE along a first and/or second direction DR1 and/or DR2 when viewed in a cross-sectional view). The side insulating layer SINS may be arranged on the lower insulating layer BINS.

Each of the source region SA and the drain region DA may be a region doped with the first type (kind) impurity. The gate electrode GE of the pixel transistor PTR may overlap the well region WA in the third direction DR3. The channel region CH may overlap the gate electrode GE in the third direction DR3. The source region SA may be arranged on one side of the gate electrode GE, and the drain region DA may be arranged on the other side of the gate electrode GE.

Each of the plurality of well regions WA further includes a first low-concentration impurity region LDD1 arranged between the channel region CH and the source region SA, and a second low-concentration impurity region LDD2 arranged between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating layer SINS1 may be arranged on the semiconductor substrate SSUB. The first semiconductor insulating layer SINS1 may be formed of silicon carbonitride (SiCN) or a silicon oxide (SiOₓ, where, e.g., 0<x≤2)-based inorganic film, but the present disclosure is not limited thereto.

A second semiconductor insulating layer SINS2 may be arranged on the first semiconductor insulating layer SINS1. The second semiconductor insulating layer SINS2 may be formed of a silicon oxide (SiOₓ)-based inorganic film, but the present disclosure is not limited thereto.

The plurality of contact terminals CTE may be arranged on the second semiconductor insulating layer SINS2. Each of the plurality of contact terminals CTE may be connected to any one of the gate electrode GE, the source region SA, and the drain region DA of each of the pixel transistors PTR through holes penetrating the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), neodymium (Nd), or an alloy including any one or more of them.

A third semiconductor insulating layer SINS3 may be arranged on a side surface of each of the plurality of contact terminals CTE. The top surface of each of the plurality of contact terminals CTE may be exposed without being covered by the third semiconductor insulating layer SINS3. The third semiconductor insulating layer SINS3 may be formed of a silicon oxide (SiOₓ)-based inorganic film, but the present disclosure is not limited thereto.

The semiconductor substrate SSUB may be replaced with a glass substrate or a polymer resin substrate such as polyimide. In such embodiments, thin film transistors may be arranged on the glass substrate or the polymer resin substrate. The glass substrate may be a rigid substrate that does not bend, and the polymer resin substrate may be a flexible substrate that can be bent or curved.

The light-emitting element backplane EBP includes a plurality of conductive layers ML1 to ML8, a plurality of vias VA1 to VA9, and a plurality of insulating layers INS1 to INS11. In addition, the light-emitting element backplane EBP may include a plurality of insulating layers INS1 to INS11 arranged between the first to eighth conductive layers ML1 to ML8.

The first to eighth conductive layers ML1 to ML8 serve to connect the plurality of contact terminals CTE exposed from the semiconductor backplane SBP to thereby implement the circuit of the first sub-pixel SP1 shown, for example, in FIG. 3. For example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In one or more embodiments, the connection between the drain region corresponding to the drain electrode of the fourth transistor T4, the source region corresponding to the source electrode of the fifth transistor T5, and a first electrode AND of the light-emitting element LE is also accomplished through the first to eighth conductive layers ML1 to ML8.

A first insulating layer INS1 may be arranged on the semiconductor backplane SBP. Each of first vias VA1 may penetrate the first insulating layer INS1 to be connected to the contact terminal CTE exposed from the semiconductor backplane SBP. The first conductive layer ML1 may be arranged on the first insulating layer INS1 and may be connected to the first vias VA1.

A second insulating layer INS2 may be arranged on the first insulating layer INS1 and the first conductive layer ML1. Each of second vias VA2 may penetrate the second insulating layer INS2 and may be connected to the exposed first conductive layer ML1. The second conductive layer ML2 may be arranged on the second insulating layer INS2 and may be connected to the second vias VA2.

A third insulating layer INS3 may be arranged on the second insulating layer INS2 and the second conductive layer ML2. Each of third vias VA3 may penetrate the third insulating layer INS3 and be connected to the exposed second conductive layer ML2. The third conductive layer ML3 may be arranged on the third insulating layer INS3 and may be connected to the third vias VA3.

A fourth insulating layer INS4 may be arranged on the third insulating layer INS3 and the third conductive layer ML3. Each of fourth vias VA4 may penetrate the fourth insulating layer INS4 and may be connected to the exposed third conductive layer ML3. The fourth conductive layer ML4 may be arranged on the fourth insulating layer INS4 and may be connected to the fourth vias VA4.

A fifth insulating layer INS5 may be arranged on the fourth insulating layer INS4 and the fourth conductive layer ML4. Each of fifth vias VA5 may penetrate the fifth insulating layer INS5 and may be connected to the exposed fourth conductive layer ML4. The fifth conductive layer ML5 may be arranged on the fifth insulating layer INS5 and may be connected to the fifth vias VA5.

A sixth insulating layer INS6 may be arranged on the fifth insulating layer INS5 and the fifth conductive layer ML5. Each of sixth vias VA6 may penetrate the sixth insulating layer INS6 and may be connected to the exposed fifth conductive layer ML5. The sixth conductive layer ML6 may be arranged on the sixth insulating layer INS6 and may be connected to the sixth vias VA6.

A seventh insulating layer INS7 may be arranged on the sixth insulating layer INS6 and the sixth conductive layer ML6. Each of seventh vias VA7 may penetrate the seventh insulating layer INS7 and may be connected to the exposed sixth conductive layer ML6. The seventh conductive layer ML7 may be arranged on the seventh insulating layer INS7 and may be connected to the seventh vias VA7.

An eighth insulating layer INS8 may be arranged on the seventh insulating layer INS7 and the seventh conductive layer ML7. Each of eighth vias VA8 may penetrate the eighth insulating layer INS8 and may be connected to the exposed seventh conductive layer ML7. The eighth conductive layer ML8 may be arranged on the eighth insulating layer INS8 and may be connected to the eighth vias VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), neodymium (Nd), or an alloy including any one or more of them. The first to eighth vias VA1 to VA8 may be made of substantially the same material. First to eighth insulating layers INS1 to INS8 may be formed of a silicon oxide (SiOₓ)-based inorganic film, but the present disclosure is not limited thereto.

The thicknesses (in the third direction DR3) of the first conductive layer ML1, the second conductive layer ML2, the third conductive layer ML3, the fourth conductive layer ML4, the fifth conductive layer ML5, and the sixth conductive layer ML6 may be greater than the thicknesses (in the third direction DR3) of the first via VA1, the second via VA2, the third via VA3, the fourth via VA4, the fifth via VA5, and the sixth via VA6, respectively. (For example, the thickness (in the third direction DR3) of the first conductive layer ML1 may be greater than the thickness (in the third direction DR3) of each of the first vias VA1. The thickness (in the third direction DR3) of the second conductive layer ML2 may be greater than the thickness (in the third direction DR3) of each of the second vias VA2. The thickness (in the third direction DR3) of the third conductive layer ML3 may be greater than the thickness (in the third direction DR3) of each of the third vias VA3. The thickness (in the third direction DR3) of the fourth conductive layer ML4 may be greater than the thickness (in the third direction DR3) of each of the fourth vias VA4. The thickness (in the third direction DR3) of the fifth conductive layer ML5 may be greater than the thickness (in the third direction DR3) of each of the fifth vias VA5. The thickness (in the third direction DR3) the sixth conductive layer ML6 may be greater than the thickness (in the third direction DR3) of each of the sixth vias VA6.) The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately (about) 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately (about) 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. (For example, the thickness of the seventh conductive layer ML7 may be greater than the thickness of each of the seventh vias VA7. The thickness of the eighth conductive layer ML8 may be greater than the thickness of each of the eighth vias VA8.) The thickness of each of the seventh vias VA7 and the eighth vias VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately (about) 9,000 Å. The thickness of each of the seventh via VA7 and the eighth via VA8 may be approximately (about) 6,000 Å.

A ninth insulating layer INS9 may be arranged on the eighth insulating layer INS8 and the eighth conductive layer ML8. The ninth insulating layer INS9 may be formed of a silicon oxide (SiOₓ)-based inorganic film, but the present disclosure is not limited thereto.

Each of ninth vias VA9 may penetrate the ninth insulating layer INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), neodymium (Nd), or an alloy including any one or more of them. The thickness of the ninth via VA9 may be approximately 16,500 Å.

The display element layer EML may be arranged on the light-emitting element backplane EBP. The display element layer EML may include light-emitting elements LE each including a reflective electrode layer RL, a tenth insulating layer INS10, a tenth via VA10, the first electrode AND, a light-emitting stack IL, and a second electrode CAT; a pixel-defining film PDL; and a plurality of trenches TRC.

The reflective electrode layer RL may be arranged on the ninth insulating layer INS9. The reflective electrode layer RL may include at least one reflective electrode and/or a step layer STPL. For example, FIG. 7 illustrates that the one or more reflective electrodes include first to fourth reflective electrodes RL1, RL2, RL3, and RL4, but the present disclosure is not limited thereto.

Each of the first reflective electrodes RL1 may be arranged on the ninth insulating layer INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), neodymium (Nd), or an alloy including any one or more of them. For example, the first reflective electrodes RL1 may contain titanium nitride (TiN).

Each of the second reflective electrodes RL2 may be arranged on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), neodymium (Nd), or an alloy including any one or more of them. For example, the second reflective electrodes RL2 may include aluminum (Al).

In the third sub-pixel SP3, the step layer STPL may be arranged on the second reflective electrode RL2. The step layer STPL may not be arranged on the second reflective electrode RL2 in the second sub-pixel SP2 and/or the first sub-pixel SP1.

The thickness of the step layer STPL may be set in consideration of the wavelength of the light of the first color and a distance from the light-emitting stack IL of the third sub-pixel SP3 to the fourth reflective electrode RL4 to increase the reflection of the light of the first color emitted from the light-emitting stack IL.

The step layer STPL may be formed of silicon carbonitride (SiCN) or a silicon oxide (SiOₓ)-based inorganic film, but the present disclosure is not limited thereto.

In the first sub-pixel SP1, the third reflective electrode RL3 may be arranged on the second reflective electrode RL2. In the second sub-pixel SP2, the third reflective electrode RL3 may be arranged on the second reflective electrode RL2. In the third sub-pixel SP3, the third reflective electrode RL3 may be arranged on the step (e.g., act or task) layer STPL. The third reflective electrode RL3 may be formed of any one of copper (Cu), aluminum (Al), tungsten (W), molybdenum (Mo), chromium (Cr), gold (Au), titanium (Ti), nickel (Ni), neodymium (Nd), or an alloy including any one or more of them. For example, the third reflective electrode RL3 may include titanium nitride (TiN).

At least one of the first reflective electrode RL1, the second reflective electrode RL2, or the third reflective electrode RL3 may not be provided.

The fourth reflective electrode RL4 may be arranged on the third reflective electrode RL3. The fourth reflective electrode RL4 may be a layer that reflects light from the light-emitting stack IL. The fourth reflective electrode RL4 may include metal having high reflectivity to improve light reflection. In one or more embodiments, because the fourth reflective electrode RL4 is an electrode that substantially reflects light from the light-emitting element LE, the thickness of the fourth reflective electrode RL4 may be greater than the thickness of each of the first reflective electrode RL1, the second reflective electrode RL2, and the third reflective electrode RL3. The fourth reflective electrode RL4 may be formed of any one of copper (Cu), aluminum (Al), tungsten (W), molybdenum (Mo), chromium (Cr), gold (Au), titanium (Ti), nickel (Ni), neodymium (Nd), or an alloy including any one or more of them. For example, the fourth reflective electrodes RL4 may include aluminum (Al) or titanium (Ti).

The tenth insulating layer INS10 may be arranged on the ninth insulating layer INS9 and the fourth reflective electrodes RL4. The tenth insulating layer INS10 may be an optical auxiliary layer through which light reflected by the reflective electrode layer RL passes, among light emitted from the light-emitting elements LE. The tenth insulating layer INS10 may be formed of a silicon oxide (SiOₓ)-based inorganic film, but the present disclosure is not limited thereto.

Each of the tenth vias VA10 may penetrate the tenth insulating layer INS10 and be connected to the exposed ninth metal layer ML9. The tenth vias VA10 may be formed of any one of copper (Cu), aluminum (Al), tungsten (W), molybdenum (Mo), chromium (Cr), gold (Au), titanium (Ti), nickel (Ni), neodymium (Nd), or an alloy including any one or more of them.

The thickness of the tenth vias VA10 may vary in the first sub-pixel SP1, the second sub-pixel SP2, and the third sub-pixel SP3 in order to adjust a resonance distance of light emitted from the light-emitting elements LE in at least one of the first sub-pixel SP1, the second sub-pixel SP2, or the third sub-pixel SP3. For example, the thickness of the tenth via VA10 in the third sub-pixel SP3 may be less than the thickness of the tenth via VA10 in each of the first sub-pixel SP1 and the second sub-pixel SP2. Further, the thickness of the tenth via VA10 in the second sub-pixel SP2 may be smaller than the thickness of the tenth via VA10 in the first sub-pixel SP1. For example, the distance between the light-emitting stack IL and the reflective electrode layer RL may be different in the first sub-pixel SP1, the second sub-pixel SP2, and the third sub-pixel SP3.

Thus, in order to adjust the distance between the light-emitting stack IL and the reflective electrode layer RL according to the main wavelength of light emitted from the first sub-pixel SP1, the presence or absence of the step layer STPL and the thickness of the step layer STPL in the first sub-pixel SP1, the second sub-pixel SP2, and the third sub-pixel SP3 may be set. For example, a step layer STPL may be provided in the first sub-pixel SP1 to reduce the distance between the fourth reflective electrode RL4 and the the light-emitting stack IL in the first sub-pixel SP1 relative to those distances in the second and third subpixels SP2, SP3. This decreased distance may correlate with the resonance distance of the first light emitted in the first sub-pixel SP1 by the light-emitting stack IL, and thus may lead to increased light reflection by the fourth reflective electrode RL4. Similarly, the distances between the fourth reflective electrodes RL4 and the light-emitting stacks IL of the second and third sub-pixels SP2, SP3 may also correlate to the resonance distances of the second and third lights, respectively, and thus may also lead to increased light reflection by those respective fourth reflective electrodes RL4.

The first electrode AND of each of the light-emitting elements LE may be arranged on the tenth insulating layer INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), neodymium (Nd), or an alloy including any one or more of them. For example, the first electrode AND of each of the light-emitting elements LE may be titanium nitride (TiN).

The pixel-defining film PDL may be arranged on a part of the first electrode AND of each of the light-emitting elements LE and the tenth insulating layer INS10. The pixel-defining film PDL may cover the edge of the first electrode AND of each of the light-emitting elements LE. The pixel-defining film PDL may serve to partition the first emission areas EA1, the second emission areas EA2, and the third emission areas EA3.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel-defining film PDL may include first to third pixel-defining films PDL1, PDL2, and PDL3. The first pixel-defining film PDL1 may be arranged on the edge of the first electrode AND of each of the light-emitting elements LE, the second pixel-defining film PDL2 may be arranged on the first pixel-defining film PDL1, and the third pixel-defining film PDL3 may be arranged on the second pixel-defining film PDL2. The first pixel-defining film PDL1, the second pixel-defining film PDL2, and the third pixel-defining film PDL3 may be formed of a silicon oxide (SiOₓ)-based inorganic film, but the present disclosure is not limited thereto. The first pixel-defining film PDL1, the second pixel-defining film PDL2, and the third pixel-defining film PDL3 may each have a thickness of about 500 Å.

When the first pixel-defining film PDL1, the second pixel-defining film PDL2, and the third pixel-defining film PDL3 are formed as one pixel-defining film, the height of the one pixel-defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel-defining film PDL1, the second pixel-defining film PDL2, and the third pixel-defining film PDL3 may have a cross-sectional structure having a stepped portion. For example, the width of the first pixel-defining film PDL1 may be greater than the width of the second pixel-defining film PDL2 and the width of the third pixel-defining film PDL3, and the width of the second pixel-defining film PDL2 may be greater than the width of the third pixel-defining film PDL3. The width of the first pixel-defining film PDL1 refers to the horizontal length of the first pixel-defining film PDL1 defined in the first direction DR1 and the second direction DR2.

Each of the plurality of trenches TRC may penetrate the first pixel-defining film PDL1, the second pixel-defining film PDL2, and the third pixel-defining film PDL3. Further, the tenth insulating layer INS10 may be partially recessed at each of the plurality of trenches TRC.

At least one trench TRC may be arranged between each of the neighboring sub-pixels SP1, SP2, and SP3. Although FIG. 7 illustrates that two trenches TRC are arranged between adjacent sub-pixels SP1, SP2, and SP3 (e.g., between the adjacent first and second sub-pixels SP1 and SP2 and between the adjacent second and third sub-pixels SP2 and SP3), the present disclosure is not limited thereto.

The light-emitting stack IL may include a plurality of intermediate layers. FIG. 7 illustrates that the light-emitting stack IL has a three-tandem structure including the first stack layer IL1, the second stack layer IL2, and the third stack layer IL3, but the present disclosure is not limited thereto. For example, the light-emitting stack IL may have a two-tandem structure including two stack layers.

In the three-tandem structure, the light-emitting stack IL may have a tandem structure including a plurality of stack layers IL1, IL2, and IL3 that emit different lights. For example, the light-emitting stack IL may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light-emitting layer that emits light of the first color, and a first electron transport layer are sequentially stacked. The second stack layer IL2 may have a structure in which a second hole transport layer, a second organic light-emitting layer that emits light of the third color, and a second electron transport layer are sequentially stacked. The third stack layer IL3 may have a structure in which a third hole transport layer, a third organic light-emitting layer that emits light of the second color, and a third electron transport layer are sequentially stacked.

A first charge generation layer for supplying charges to the second stack layer IL2 and supplying electrons to the first stack layer IL1 may be arranged between the first stack layer IL1 and the second stack layer IL2. The first charge generation layer may include an N-type (kind) charge generation layer that supplies electrons to the first stack layer IL1 and a P-type (kind) charge generation layer that supplies holes to the second stack layer IL2. The N-type (kind) charge generation layer may include a dopant of a metal material.

A second charge generation layer for supplying charges to the third stack layer IL3 and supplying electrons to the second stack layer IL2 may be arranged between the second stack layer IL2 and the third stack layer IL3. The second charge generation layer may include an N-type (kind) charge generation layer that supplies electrons to the second stack layer IL2 and a P-type (kind) charge generation layer that supplies holes to the third stack layer IL3.

The first stack layer IL1 may be arranged on the first electrodes AND and the pixel-defining film PDL. A remaining stack layer RIL made of the same material as the first stack layer IL1 may be arranged on the bottom surface of each of the trenches TRC. Due to the trench TRC, the first stack layer IL1 may be cut off between the neighboring sub-pixels SP1, SP2, and SP3. The second stack layer IL2 may be arranged on the first stack layer IL1. Due to the trench TRC, the second stack layer IL2 may be cut off between the neighboring sub-pixels SP1, SP2, and SP3. A void ESS or an empty space may be arranged between the remaining stack layer RIL and the second stack layer IL2 in each trench TRC. The third stack layer IL3 may be arranged on the second stack layer IL2. The third stack layer IL3 may not be cut off by the trench TRC and may be arranged to cover the second stack layer IL2 in each of the trenches TRC. For example, in the three-tandem structure, each of the plurality of trenches TRC may be a structure for cutting off the first to second stack layers IL1 and IL2, the first charge generation layer, and the second charge generation layer of the display element layer EML between the neighboring sub-pixels SP1, SP2, and SP3.

In one or more embodiments, in the two-tandem structure, each of the plurality of trenches TRC may be a structure for cutting off the charge generation layer and the lower stack layer arranged between the lower stack layer and the upper stack layer.

In order to stably cut off the first stack layer IL1 of the display element layer EML between adjacent sub-pixels SP1, SP2, and SP3, the height of each of the plurality of trenches TRC may be greater than the height of the pixel-defining film PDL. The height of each of the plurality of trenches TRC refers to the length of each of the plurality of trenches TRC in the third direction DR3. The height of the pixel-defining film PDL refers to the length of the pixel-defining film PDL in the third direction DR3. In order to cut off the first to third stack layers IL1, IL2, and IL3 of the display element layer EML between the neighboring sub-pixels SP1, SP2, and SP3, another structure may exist instead of the trench TRC. For example, instead of the trench TRC, a reverse tapered partition wall may be arranged on the pixel-defining film PDL.

In addition, FIGS. 7 and 8 illustrate that the first to third stack layers IL1, IL2, and IL3 are all arranged in the first emission area EA1, the second emission area EA2, and the third emission area EA3, but the present disclosure is not limited thereto. For example, the first stack layer IL1 may be arranged in the first emission area EA1, and may not be provided from the second emission area EA2 and the third emission area EA3. Furthermore, the second stack layer IL2 may be arranged in the second emission area EA2 and may not be provided from the first emission area EA1 and the third emission area EA3. Further, the third stack layer IL3 may be arranged in the third emission area EA3 and may not be provided from the first emission area EA1 and the second emission area EA2. In such embodiments, first to third color filters CF1, CF2, and CF3 of the optical layer OPL may not be provided.

The second electrode CAT may be arranged on the third stack layer IL3. The second electrode CAT may be arranged on the third stack layer IL3 in each of the plurality of trenches TRC. The second electrode CAT may be formed of a transparent conductive material (TCO) such as ITO or IZO that can transmit light, or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be arranged on the display element layer EML. The encapsulation layer TFE may include at least one inorganic film TFE1, TFE2, TFE3, and/or TFE4 to reduce or prevent oxygen or moisture from permeating into the display element layer EML. For example, the encapsulation layer TFE may include a first sub-encapsulation layer TFE1, a second sub-encapsulation layer TFE2, a third sub-encapsulation layer TFE3, and a fourth sub-encapsulation layer TFE4, which are sequentially stacked along the thickness direction (e.g., the third direction DR3) of the encapsulation layer TFE. Here, the first sub-encapsulation layer TFE1, the third sub-encapsulation layer TFE3, and the fourth sub-encapsulation layer TFE4 may each include an inorganic material, and the second sub-encapsulation layer TFE2 may include an organic material.

The first sub-encapsulation layer TFE1 may be arranged on the second electrode CAT. The first sub-encapsulation layer TFE1 may be formed as a multilayer in which one or more inorganic films selected from among silicon nitride (SiₓN_{y}, where, e.g., 0<x≤3 and 0<y≤4), silicon oxynitride (SiOₓN_{y}, where, e.g., 0 <x≤2 and 0<y≤2), and silicon oxide (SiOₓ) are alternately stacked. The first sub-encapsulation layer TFE1 may be formed by a chemical vapor deposition (CVD) process. The thickness of the first sub-encapsulation layer TFE1 may be smaller than or equal to 1 μm.

The second sub-encapsulation layer TFE2 may be arranged on the first sub-encapsulation layer TFE1. For example, the second sub-encapsulation layer TFE2 may be arranged between the first sub-encapsulation layer TFE1 and the third sub-encapsulation layer TFE3. The second sub-encapsulation layer TFE2 may be in contact (e.g., direct contact) with each of the first sub-encapsulation layer TFE1 and the third sub-encapsulation layer TFE3. The second sub-encapsulation layer TFE2 may be an organic film such as acryl resin, epoxy resin, phenolic resin, polyamide resin, polyimide resin and/or the like.

The third sub-encapsulation layer TFE3 may be arranged on the second sub-encapsulation layer TFE2. For example, the third sub-encapsulation layer TFE3 may be arranged between the second sub-encapsulation layer TFE2 and the fourth sub-encapsulation layer TFE4. The third sub-encapsulation layer TFE3 may be in contact (e.g., direct contact) with each of the second sub-encapsulation layer TFE2 and the fourth sub-encapsulation layer TFE4. The third sub-encapsulation layer TFE3 may be formed as a multilayer in which one or more inorganic films selected from among silicon nitride (SiₓN_{y}), silicon oxynitride (SiOₓN_{y}), and silicon oxide (SiOₓ) are alternately stacked. The third sub-encapsulation layer TFE3 may be formed by a chemical vapor deposition (CVD) process.

The fourth sub-encapsulation layer TFE4 may be arranged on the third sub-encapsulation layer TFE3. For example, the fourth sub-encapsulation layer TFE4 may be arranged between the third sub-encapsulation layer TFE3 and an organic layer APL. The fourth sub-encapsulation layer TFE4 may be in contact (e.g., direct contact) with each of the third sub-encapsulation layer TFE3 and the organic layer APL. The fourth sub-encapsulation layer TFE4 may be arranged at the uppermost side among the sub-encapsulation layers TFE1 to TFE4 of the encapsulation layer TFE. The fourth sub-encapsulation layer TFE4 may be formed of titanium oxide (TiOₓ) or aluminum oxide (AlOₓ; for example, Al₂O₃), but the present disclosure is not limited thereto. The fourth sub-encapsulation layer TFE4 may be formed by an atomic layer deposition (ALD) process.

The organic layer APL may be a layer for increasing the interfacial adhesion between the encapsulation layer TFE and the optical layer OPL. The organic layer APL may be an organic film such as acrylic resin, epoxy resin, phenolic resin, polyamide resin, or polyimide resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be arranged on the adhesive organic layer APL.

The first color filter CF1 may overlap the first emission area EA1 of the first sub-pixel SP1. The first color filter CF1 may be to transmit light of the first color, i.e., light of a red wavelength band. Thus, the first color filter CF1 may be to transmit light of the first color among light emitted from the first emission area EA1.

The second color filter CF2 may overlap the second emission area EA2 of the second sub-pixel SP2. The second color filter CF2 may be to transmit light of the second color, i.e., light of a green wavelength band. Thus, the second color filter CF2 may be to transmit light of the second color among light emitted from the second emission area EA2.

The third color filter CF3 may overlap the third emission area EA3 of the third sub-pixel SP3. The third color filter CF3 may be to transmit light of the third color, i.e., light of a blue wavelength band. Thus, the third color filter CF3 may be to transmit light of the third color among light emitted from the third emission area EA3.

The plurality of lenses LNS may be arranged on the first color filter CF1, the second color filter CF2, and the third color filter CF3, respectively. Each of the plurality of lenses LNS may be a structure for increasing the proportion of light directed to the front of the display device 10. Although each of the lenses LNS is illustrated as having a cross-sectional shape that is convex upward, the present disclosure is not limited thereto.

The filling layer FIL may be arranged on the plurality of lenses LNS. The filling layer FIL may have a set or predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be arranged on the filling layer FIL. The cover layer CVL may be a glass substrate or a polymer resin. When the cover layer CVL is a glass substrate, it may be attached onto the filling layer FIL. In such embodiments, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be arranged on one surface of the cover layer CVL. The polarizing plate POL may be a structure for reducing or preventing visibility degradation caused by the reflection of external light. The polarizing plate POL may include a linear polarizing plate and a phase retardation film. For example, the phase retardation film may be a λ/4 plate (quarter-wave plate), but the present disclosure is not limited thereto. However, for example, if (e.g., when) visibility degradation caused by the reflection of external light is sufficiently overcome by the first to third color filters CF1, CF2, and CF3, the polarizing plate POL may not be provided.

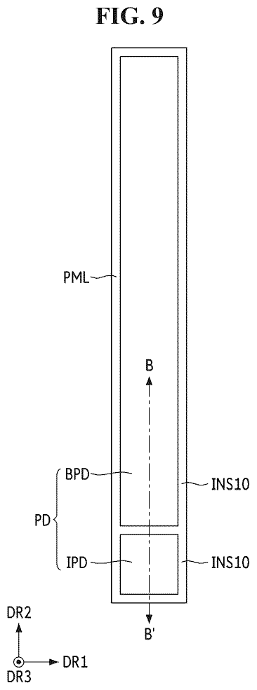

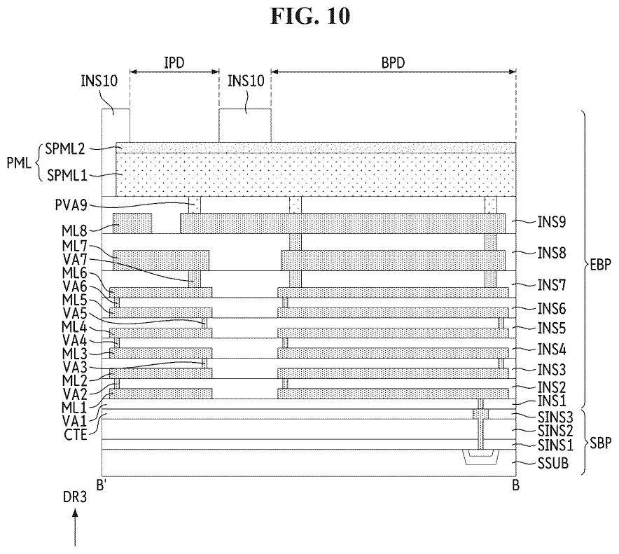

FIG. 9 is a layout diagram illustrating a first pad PD1 of the first pad portion PDA1 of FIG. 4, according to one or more embodiments of the present disclosure. FIG. 10 is a cross-sectional view taken along the line B-B′ of FIG. 9, according to one or more embodiments of the present disclosure.

Referring to FIGS. 9 and 10, each of the first pads PD1 includes a first sub-pad BPD and a second sub-pad IPD in which a pad metal layer PML is partitioned by the tenth insulating layer INS10. Both the first sub-pad BPD and the second sub-pad IPD may be electrically connected to a pad or bump of the circuit board 300 through a conductive adhesive member. In one or more embodiments, the second sub-pad IPD may be a pad connected to a jig or probe pin during an inspection process or connected to a circuit board for inspection.

The area of the first sub-pad BPD may be larger than the area of the second sub-pad IPD. The length of the first sub-pad BPD in the first direction DR1 may be substantially the same as the length of the second sub-pad IPD in the first direction DR1. The length of the first sub-pad BPD in the second direction DR2 may be greater than the length of the second sub-pad IPD in the second direction DR2.

The pad metal layer PML may include a first sub-pad metal layer SPML1 and a second sub-pad metal layer SPML2. The first sub-pad metal layer SPML1 may be formed of any one of copper (Cu), aluminum (Al), tungsten (W), molybdenum (Mo), chromium (Cr), gold (Au), titanium (Ti), nickel (Ni), neodymium (Nd), or an alloy including any one or more of them. The second sub-pad metal layer SPML2 may be formed of any one of copper (Cu), aluminum (Al), tungsten (W), molybdenum (Mo), chromium (Cr), gold (Au), titanium (Ti), nickel (Ni), neodymium (Nd), or an alloy including any one or more of them. For example, the first sub-pad metal layer SPML1 may be made of aluminum (Al) and may have a thickness of approximately 12,000 Å. In one or more embodiments, the second sub-pad metal layer SPML2 may be made of titanium nitride (TiN) and may have a thickness of approximately 600 Å. The thickness of the pad metal layer PML may be greater than the thickness of the reflective electrode layer RL.

A portion of the top surface of the second sub-pad metal layer SPML2 corresponding to the first sub-pad BPD may be exposed without being covered by the tenth insulating layer INS10. The top surface of the second sub-pad metal layer SPML2 corresponding to the second sub-pad IPD may be exposed without being covered by the tenth insulating layer INS10. The first sub-pad metal layer SPML1 may be connected to one or more pad vias PVA9 that penetrates the ninth insulating layer INS9 to be connected to the eighth conductive layer ML8.

As illustrated in FIGS. 9 and 10, because the pad metal layer PML of the first sub-pad BPD and the pad metal layer PML of the second sub-pad IPD are formed integrally, if (e.g., when) the pad metal layer PML of the second sub-pad IPD is damaged or broken during an inspection process, the pad metal layer PML of the first sub-pad BPD may also be damaged or broken. Accordingly, it is desirable and/or necessary to separate or distinguish the pad metal layer PML of the second sub-pad IPD and the pad metal layer PML of the first sub-pad BPD used in an inspection process.

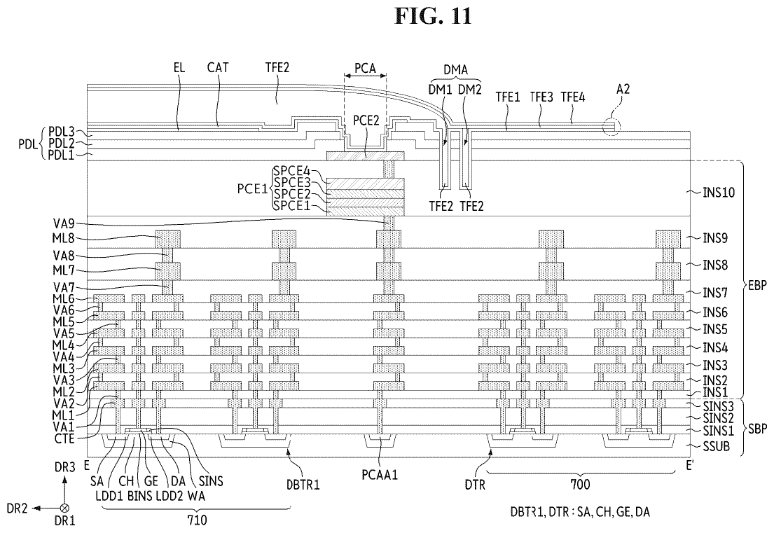

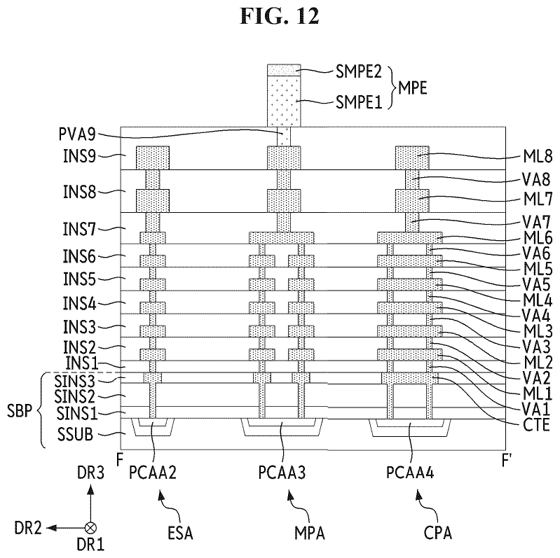

FIG. 11 is a cross-sectional view illustrating a portion of a display panel taken along the line E-E′ of FIG. 4, according to one or more embodiments of the present disclosure. FIG. 12 is a cross-sectional view illustrating a portion of a display panel taken along the line F-F′ of FIG. 4, according to one or more embodiments of the present disclosure.

FIGS. 11 and 12 illustrate the first distribution circuit 710, a power connection portion PCA, a dam portion DMA, the data driver 700, the first pad portion PDA1, an electrostatic protection portion ESA, a permeation prevention portion MPA, and a crack prevention portion CPA arranged on one side of the display area DA.

On one side of the display area DA, the first distribution circuit 710, the power connection portion PCA, the dam portion DMA, the data driver 700, the first pad portion PDA1, the electrostatic protection portion ESA, the permeation prevention portion MPA, and the crack prevention portion CPA may be sequentially arranged in the second direction DR2. However, the present disclosure is not limited thereto, and the power connection portion PCA may overlap the first distribution circuit 710 or the data driver 700 in the third direction DR3, and the dam portion DMA may overlap the first distribution circuit 710 or the data driver 700 in the third direction DR3.

The first distribution circuit 710 may include a plurality of first distribution transistors DBTR1. Because each of the plurality of first distribution transistors DBTR1 may be formed substantially the same as the pixel transistors PTR described in conjunction with FIG. 7, a redundant description of the plurality of first distribution transistors DBTR1 may not be provided. In one or more embodiments, because the first to eighth metal layers ML1 to ML8 and the first to eighth vias VA1 to VA8 electrically connected to the plurality of first distribution transistors DBTR1 are also substantially the same as those described in conjunction with FIG. 7, a redundant description thereof may not be provided.

The power connection portion PCA includes a first power connection area PCAA1 of the semiconductor substrate SSUB, a first power connection electrode PCE1, and a second power connection electrode PCE2.

The first driving voltage VSS may be applied to the first power connection area PCAA1 of the semiconductor substrate SSUB.

The first power connection electrode PCE1 may be arranged on the ninth insulating layer INS9. The first power connection electrode PCE1 may be connected to the first power connection area PCAA of the semiconductor substrate SSUB through the first to eighth metal layers ML1 to ML8 and the first to eighth vias VA1 to VA8.

The first power connection electrode PCE1 may include first to fourth sub-power connection electrodes SPCE1 to SPCE4. The first to fourth sub-power connection electrodes SPCE1 to SPCE4 of the first power connection electrode PCE1 may be substantially the same as the first to fourth reflective electrodes RL1 to RL4 of the reflective electrode layer RL. For example, the first sub-power connection electrode layer SPCE1 may correspond to the first reflective electrode RL1, the second sub-power connection electrode layer SPCE2 may correspond to the second reflective electrode RL2, the third sub-power connection electrode layer SPCE3 may correspond to the third reflective electrode RL3, and the fourth sub-power connection electrode layer SPCE4 may correspond to the fourth reflective electrode RL4.

The second power connection electrode PCE2 may be arranged on the tenth insulating layer INS10. The second power connection electrode PCE2 may be connected to the first power connection electrode PCE1 through the tenth via VA10. The second power connection electrode PCE2 may include substantially the same material as the first electrode AND of the light-emitting element LE. The second power connection electrode PCE2 may be partitioned by the pixel-defining film PDL. The second electrode CAT of the light-emitting element LE may be connected to the second power connection electrode PCE2 that is exposed and not covered by the pixel-defining film PDL.

The dam portion DMA includes a first dam DM1 and a second dam DM2. The first dam DM1 and the second dam DM2 may be substantially the same as the trenches TR. Each of the first dam DM1 and the second dam DM2 may penetrate the first pixel-defining film PDL1, the second pixel-defining film PDL2, and the third pixel-defining film PDL3. The tenth interlayer insulating layer INS10 may be partially recessed at each of the first dam DM1 and the second dam DM2.

In each of the first dam DM1 and the second dam DM2, the first encapsulation inorganic film TFE1 may be arranged on the bottom surface, the encapsulation organic film TFE2 may be arranged on the first encapsulation inorganic film TFE1, and the second encapsulation inorganic film TFE3 may be arranged on the encapsulation organic film TFE2. The encapsulation organic film TFE2 may be arranged to fill a part of each of the first dam DM1 and the second dam DM2. Alternatively, in one or more embodiments, the encapsulation organic film TFE2 may not be arranged on each of the first dam DM1 and the second dam DM2. For example, the first encapsulation inorganic film TFE1 and the third encapsulation inorganic film TFE3 may be arranged in each of the first dam DM1 and the second dam DM2.

The first dam DM1 and the second dam DM2 may prevent or reduce the likelihood of the encapsulation organic film TFE2 flowing to the first pad portion PDA1 and covering the first pads PD1. When the encapsulation organic film TFE2 covers the first pads PD1, the first pads PD1 may not be electrically connected to the circuit board 300.

The data driver 700 may include a plurality of data transistors DTR. Because each of the plurality of data transistors DTR may be formed substantially the same as the pixel transistors PTR described in conjunction with FIG. 7, a redundant description of the plurality of data transistors DTR may not be provided. In one or more embodiments, because the first to eighth metal layers ML1 to ML8 and the first to eighth vias VA1 to VA8 electrically connected to the plurality of data transistors DTR are also substantially the same as those described in conjunction with FIG. 7, a redundant description thereof may not be provided.

The electrostatic protection portion ESA includes a second power connection area PCAA2 of the semiconductor substrate SSUB.

The first driving voltage VSS may be applied to the second power connection area PCAA2 of the semiconductor substrate SSUB. The second power connection area PCAA2 may be connected to the first to eighth metal layers ML1 to ML8 and the first to eighth vias VA1 to VA8. Accordingly, the electrostatic protection portion ESA may discharge static electricity applied from the outside to the first driving voltage VSS.

The permeation prevention portion MPA includes a permeation prevention electrode MPE and a third power connection area PCAA3 of the semiconductor substrate SSUB.

The first driving voltage VSS may be applied to the third power connection area PCAA3 of the semiconductor substrate SSUB. Alternatively, in one or more embodiments, the third power connection area PCAA3 of the semiconductor substrate SSUB may be electrically floating.

The permeation prevention electrode MPE may be substantially the same as the pad metal layer PML illustrated in FIG. 10.

The permeation prevention electrode MPE may include a first sub-permeation prevention electrode SMPE1 and a second sub-permeation prevention electrode SMPE2. The first sub-permeation prevention electrode SMPE1 and the second sub-permeation prevention electrode SMPE2 of the permeation prevention electrode MPE may be substantially the same as the first sub-pad electrode SPML1 and the second sub-pad electrode SPML2, respectively, as illustrated in FIG. 10. For example, the first sub-permeation prevention electrode SMPE1 may correspond to the first sub-pad electrode SPML1, and the second sub-permeation prevention electrode SMPE2 may correspond to the second sub-pad electrode SPML2.

The crack prevention portion CPA includes a fourth power connection area PCAA4 of the semiconductor substrate SSUB.

The first driving voltage VSS may be applied to the fourth power connection area PCAA4 of the semiconductor substrate SSUB. Alternatively, in one or more embodiments, the fourth power connection area PCAA4 of the semiconductor substrate SSUB may be electrically floating. The fourth power connection area PCAA4 may be connected to the first to eighth metal layers ML1 to ML8 and the first to eighth vias VA1 to VA8.

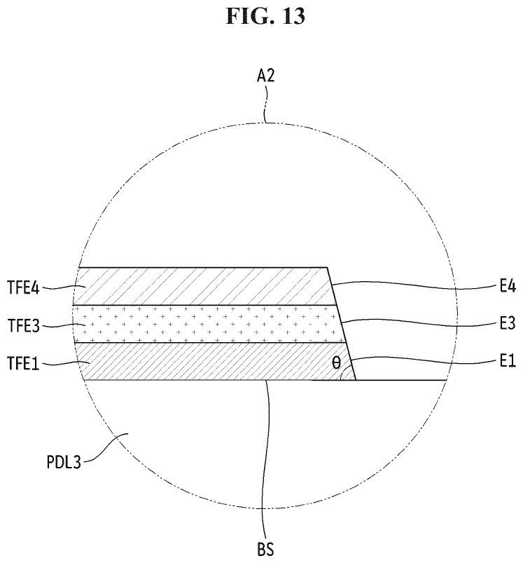

FIG. 13 is an enlarged view of the area A2 of FIG. 11, according to one or more embodiments of the present disclosure.

According to the display device of one or more embodiments, as in the example illustrated in FIGS. 12 and 13, the ends of the first sub-encapsulation layer TFE1, the third sub-encapsulation layer TFE3, and the fourth sub-encapsulation layer TFE4 may be arranged (aligned) in a row along a diagonal direction. For example, the end (hereinafter, a first end E1) of the first sub-encapsulation layer TFE1, the end (hereinafter, a third end E3) of the third sub-encapsulation layer TFE3, and the end (hereinafter, a fourth end E4) of the fourth sub-encapsulation layer TFE4 may be arranged (aligned) on an imaginary diagonal line along a fourth direction.

An angle θ between the first end E1 of the first sub-encapsulation layer TFE1 and a bottom surface BS of the first sub-encapsulation layer TFE1 may be an acute angle. For example, the angle between the first end E1 and the bottom surface BS of the first sub-encapsulation layer TFE1 may be 30 degrees to 60 degrees.

Here, the bottom surface BS of the first sub-encapsulation layer TFE1 may be an interface between the third pixel-defining film PDL3 and the first sub-encapsulation layer TFE1.

The angle between the third end E3 of the third sub-encapsulation layer TFE3 and the aforementioned bottom surface BS may be an acute angle. For example, the angle between the third end E3 of the third sub-encapsulation layer TFE3 and the bottom surface BS may be 30 degrees to 60 degrees.

The angle between the fourth end E4 of the fourth sub-encapsulation layer TFE4 and the aforementioned bottom surface BS may be an acute angle. For example, the angle between the fourth end E4 of the fourth sub-encapsulation layer TFE4 and the bottom surface BS may be 30 degrees to 60 degrees.

The angle between the first end E1 and the bottom surface BS, the angle between the third end E3 and the bottom surface BS, and the angle between the fourth end E4 and the bottom surface BS may be equal to each other.

According to one or more embodiments, the first sub-encapsulation layer TFE1, the third sub-encapsulation layer TFE3, and the fourth sub-encapsulation layer TFE4 may be fabricated by a photolithography process using one mask (e.g., the same mask), so that the first end E1 of the first sub-encapsulation layer TFE1, the third end E3 of the third sub-encapsulation layer TFE3, and the fourth end E4 of the fourth sub-encapsulation layer TFE4 may be arranged along an imaginary diagonal line. Further, because the first sub-encapsulation layer TFE1, the third sub-encapsulation layer TFE3, and the fourth sub-encapsulation layer TFE4 are fabricated by a photolithography process using one mask (e.g., the same mask), the angle between the first end E1 and the bottom surface BS, the angle between the third end E3 and the bottom surface BS, and the angle between the fourth end E4 and the bottom surface BS may be equal to each other.

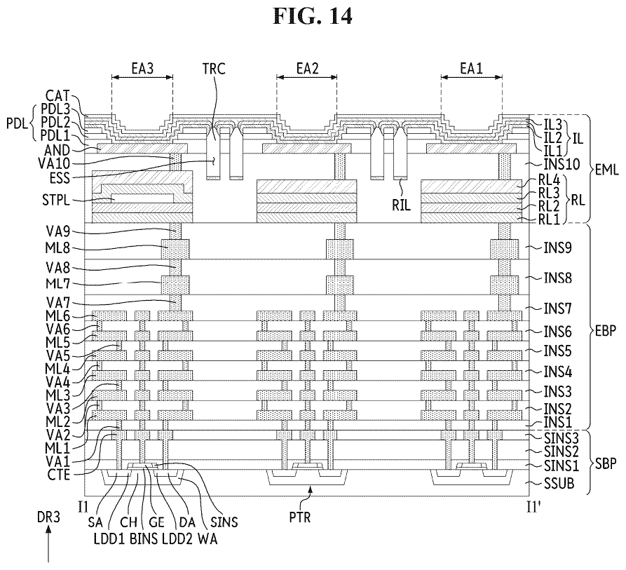

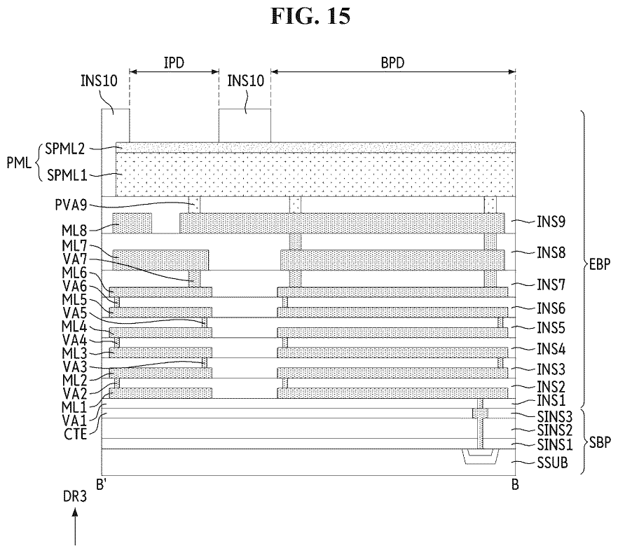

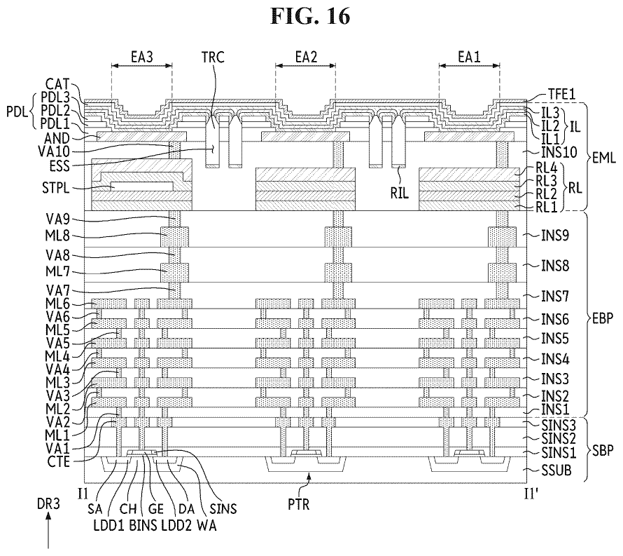

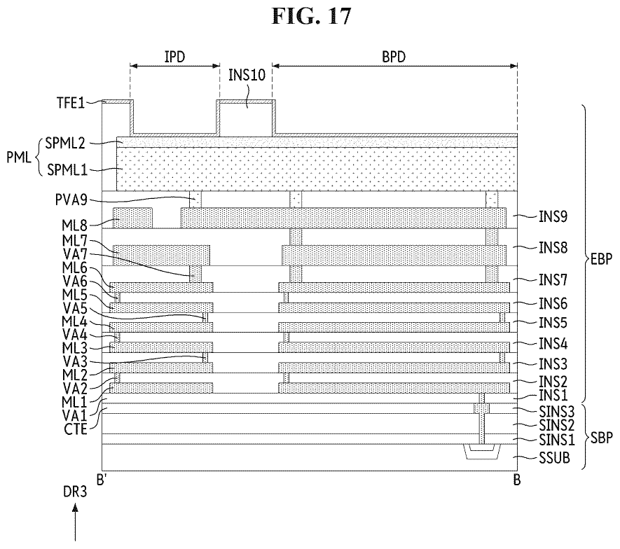

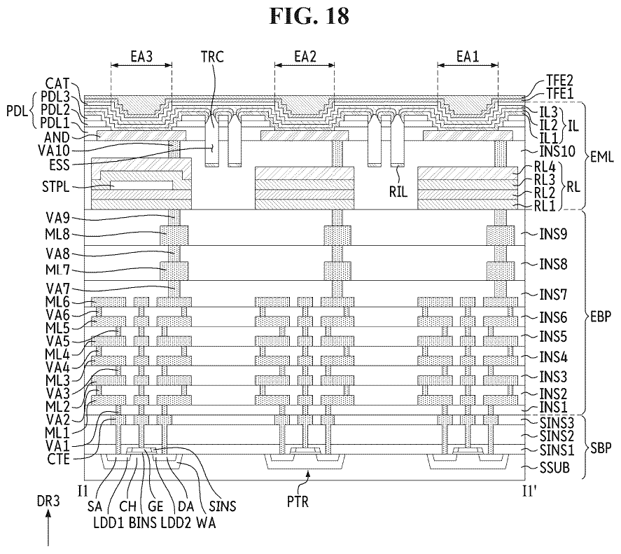

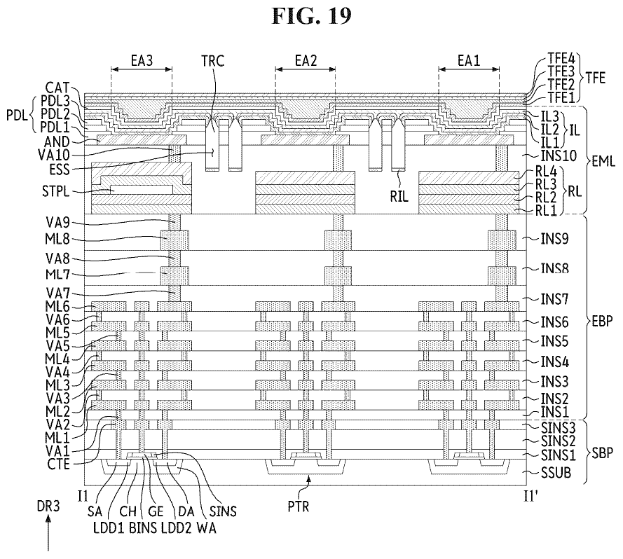

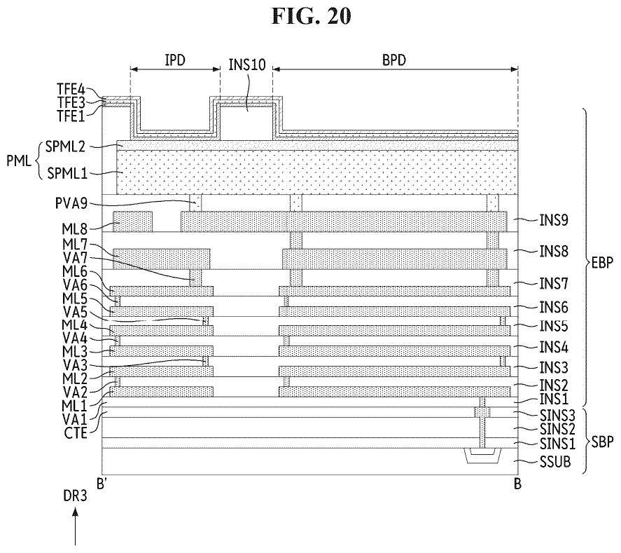

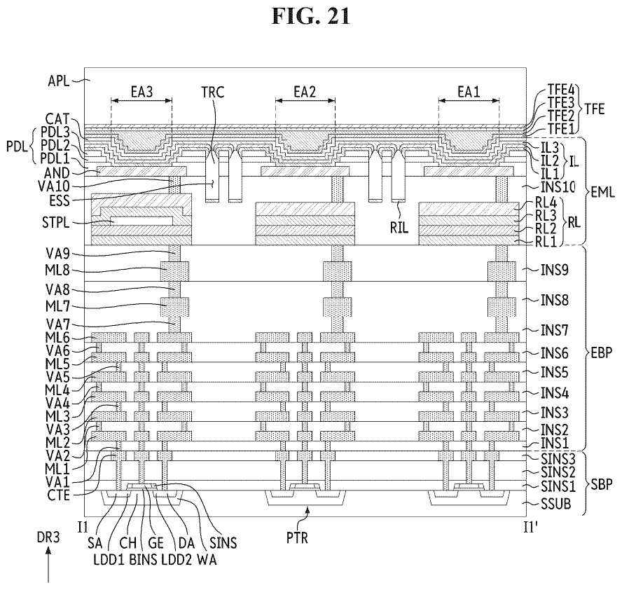

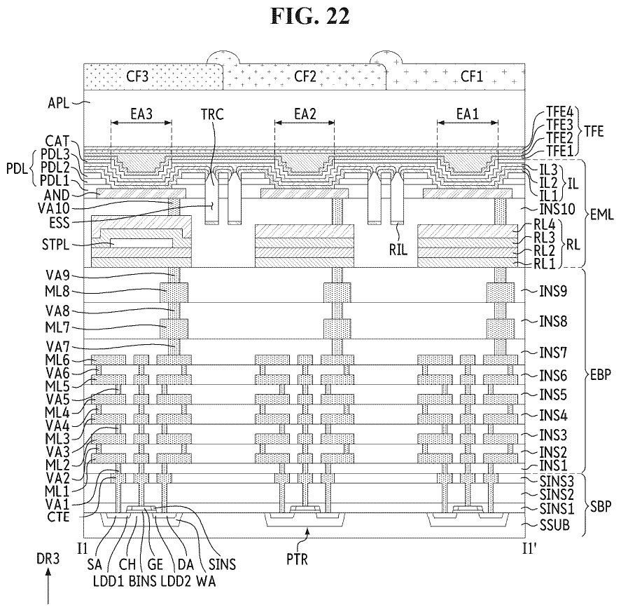

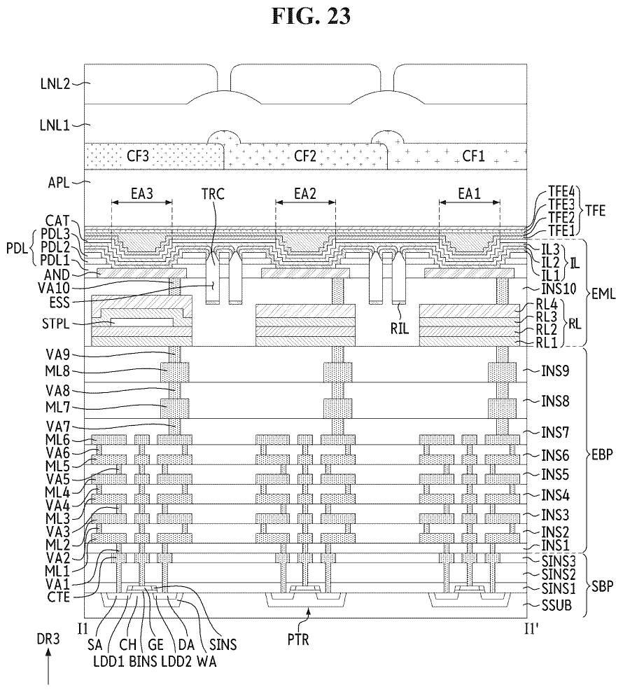

FIGS. 14 to 28 are cross-sectional views illustrating a method for fabricating a display device according to one or more embodiments of the present disclosure.

First, as shown in FIGS. 14 and 15, the light-emitting element backplane EBP may be formed on the semiconductor substrate SSUB, and the display element layer EML including the light-emitting elements LE may be formed on the light-emitting element backplane EBP.

Thereafter, as shown in FIGS. 16 and 17, the first sub-encapsulation layer TFE1 covering the light-emitting elements LE may be formed on the display element layer EML. For example, the first sub-encapsulation layer TFE1 may be formed on the second electrode CAT, the pad metal layer PML of the first pad PD1, and the tenth insulating layer INS10. In such embodiments, the first sub-encapsulation layer TFE1 may be formed on the entire surface of the semiconductor substrate SSUB including the second electrode CAT, the pad metal layer PML of the first pad PD1, and the tenth insulating layer INS10. The first sub-encapsulation layer TFE1 may be formed by a chemical vapor deposition (CVD) process.

Next, as illustrated in FIG. 18, the second sub-encapsulation layer TFE2 may be formed on the first sub-encapsulation layer TFE1. The second sub-encapsulation layer TFE2 may be selectively formed in the display area DAA and its peripheral edge by a deposition mask. The second sub-encapsulation layer TFE2 may not be arranged on the pad metal layer PML of the first pad PD1. For example, the second sub-encapsulation layer TFE2 may not be arranged on the first sub-encapsulation layer TFE1 on the pad metal layer PML of the first pad PD1.

Next, as illustrated in FIGS. 19 and 20, the third sub-encapsulation layer TFE3 may be formed on the first sub-encapsulation layer TFE1 and the second sub-encapsulation layer TFE2 and, then the fourth sub-encapsulation layer TFE4 may be formed on the third sub-encapsulation layer TFE3. In such embodiments, the third sub-encapsulation layer TFE3 may be formed on the entire surface of the semiconductor substrate SSUB including the first sub-encapsulation layer TFE1 and the second sub-encapsulation layer TFE2. The third sub-encapsulation layer TFE3 may be formed by a chemical vapor deposition (CVD) process. Further, the fourth sub-encapsulation layer TFE4 may be formed on the entire surface of the semiconductor substrate SSUB including the third sub-encapsulation layer TFE3.

The fourth sub-encapsulation layer TFE4 may be formed by an atomic layer deposition (ALD) process.

In one or more embodiments, as illustrated in FIG. 20, the second sub-encapsulation layer TFE2 is not arranged on the pad metal layer PML of the first pad PD1, so that the first sub-encapsulation layer TFE1 and the third sub-encapsulation layer TFE3 may be in contact with each other on the pad metal layer PML of the first pad PD1.

Next, as illustrated in FIG. 21, the organic layer APL may be formed on the encapsulation layer TFE (e.g., the fourth sub-encapsulation layer TFE4). In such embodiments, the organic layer APL is not formed on the pad metal layer PML of the first pad PD1.

Thereafter, as illustrated in FIG. 22, on the organic layer APL, the first color filters CF1 overlapping the first emission areas EA1 may be formed, the second color filters CF2 overlapping the second emission areas EA2 may be formed, and the third color filters CF3 overlapping the third emission areas EA3 may be formed. In one or more embodiments, the first color filters CF1, the second color filters CF2, and the third color filters CF3 are not formed on the pad metal layer PML of the first pad PD1 (see, e.g., FIG. 24).

Next, as illustrated in FIGS. 23 and 24, a first lens pattern layer LNL1 may be formed on the color filters CF1, CF2, and CF3, and a second lens pattern layer LNL2 may be formed on the first lens pattern layer LNL1. In such embodiments, the first lens layer LNL1 may be formed not only on the color filters CF1, CF2, and CF3, but also on the fourth sub-encapsulation layer TFE4 in the first pad portion PDA1 (see, e.g., FIG. 4) and the second pad portion PDA2. For example, as illustrated in FIG. 24, the first lens pattern layer LNL1 and the second lens pattern layer LNL2 may be formed on the pad metal layer PML of the first pad PD1.

The second lens pattern layer LNL2 may be formed by a photolithography process. The second lens pattern layer LNL2 may have an upwardly convex pattern shape on the first lens pattern layer LNL1 arranged on the color filters CF1, CF2, and CF3. The second lens pattern layer LNL2 may not be arranged at the edges of the color filters CF1, CF2, and CF3. For example, the second lens pattern layers LNL2 may be arranged to be spaced and/or apart (e.g., spaced apart or separated) from each other.

Further, the second lens pattern layer LNL2 may be formed on the first lens layer LNL1 arranged on the second sub-pad conductive layer SPML2 and the tenth insulating layer INS10 in the first pad portion PDA1 (see, e.g., FIG. 4) and the second pad portion PDA2. The second lens pattern layer LNL2 may not have a convex pattern shape in the first pad portion PDA1 (see, e.g., FIG. 4) and the second pad portion PDA2, and may be formed flat (e.g., may have a flat upper surface) as shown in, for example, FIG. 24, showing the first pad portion PDA1.

Thereafter, as shown in FIGS. 25 and 26, the plurality of lenses LNS may be formed by selectively removing the first lens pattern layer LNL1 and the second lens pattern layer LNL2 by dry etching. Because the second lens pattern layer LNL2 arranged on the plurality of color filters CF1, CF2, and CF3 has an upwardly convex shape, the plurality of lenses LNS may be patterned to have an upwardly convex shape similar to the second lens pattern layer LNL2.

The thickness of the first lens pattern layer LNL1 may be greater than the thickness of the second lens pattern layer LNL2. For example, the first lens pattern layer LNL1 may have a thickness of approximately 2.5 μm, and the second lens pattern layer LNL2 may have a thickness of approximately 1.5 μm. In such embodiments, if (e.g., when) the thickness of the first lens pattern layer LNL1 etched by dry etching is greater than the thickness of the second lens pattern layer LNL2 and smaller than the total thickness of the first lens pattern layer LNL1, the first lens pattern layer LNL1 may remain in the area where the second lens pattern layer LNL2 is not formed even if the first lens pattern layer LNL1 and the second lens pattern layer LNL2 are etched together. Accordingly, the plurality of colors filters CF1, CF2, and CF3 may be protected. However, the present disclosure is not limited thereto, and the entire first lens pattern layer LNL1 arranged in the area where the second lens pattern layer LNL2 is not formed may be etched. In such embodiments, as shown in FIG. 25, the plurality of lenses LNS may be arranged to be spaced and/or apart (e.g., spaced apart or separated) from each other.

In the in the first pad portion PDA1 and the second pad portion PDA2 the second lens pattern layer LNL2 may be removed through the etching process, as shown, for example, in FIG. 26.

The first lens pattern layer LNL1 and the second lens pattern layer LNL2 may be made of the same material. Alternatively, in one or more embodiments, if (e.g., when) the first lens pattern layer LNL1 and the second lens pattern layer LNL2 are made of different materials, the etching ratio of the first lens pattern layer LNL1 and the etching ratio of the second lens pattern layer LNL2 by an etching gas used in dry etching may be substantially the same.

Thereafter, as shown in FIGS. 27 and 28, the second encapsulation inorganic film TFE2 and the first lens pattern layer LNL1 arranged on the second sub-pad conductive layer SPML2 in the first pad portion PDA1 (see, e.g., FIG. 4) and the second pad portion PDA2 may be removed.

Because the second lens pattern layer LNL2 is arranged in the entire area of the first sub-pad BPD and the second sub-pad IPD, the first lens pattern layer LNL1 may remain without being removed in the first pad portion PDA1 and the second pad portion PDA2 (see, e.g., FIG. 4) in the etching step (e.g., act or task) of FIG. 26. Thus, only the second lens pattern layer LNL2 may be removed during the etching step (e.g., act or task) of FIG. 26.

Next, as shown in FIG. 27 and FIG. 28, the first lens pattern layer LNL1, the fourth sub-encapsulation layer TFE4, the third sub-encapsulation layer TFE3, and the first sub-encapsulation layer TFE1 may be removed based on the mask pattern MP. In such embodiments, the mask pattern MP may be formed in areas except the first pad portion PDA1 and the second pad portion PDA2 (see, e.g., FIG. 4). By performing etching using the mask pattern MP, as shown in FIG. 28, the first lens pattern layer LNL1, the fourth sub-encapsulation layer TFE4, the third sub-encapsulation layer TFE3, and the first sub-encapsulation layer TFE1 of the first pad portion PDA1 may be removed, so that the fourth sub-encapsulation layer TFE4, the third sub-encapsulation layer TFE3, and the first sub-encapsulation layer TFE1 may be patterned and, also, the second sub-pad metal layer SPML2 of the pad metal layer PML may be exposed. Accordingly, the fourth sub-encapsulation layer TFE4, the third sub-encapsulation layer TFE3, and the first sub-encapsulation layer TFE1 may be patterned so as not to be formed in a dead space area of the semiconductor substrate SSUB, and the first pad of the first pad portion and the second pad of the second pad portion may be respectively exposed. In such embodiments, when the etching process using the aforementioned mask pattern MP is completed, as illustrated in FIG. 13, the ends E1, E3, and E4 of the first sub-encapsulation layer TFE1, the third sub-encapsulation layer TFE3, and the fourth sub-encapsulation layer TFE4 may be arranged in a row along the diagonal direction. Further, the angle between the first end E1 of the first sub-encapsulation layer TFE1 and the bottom surface BS, the angle between the third end E3 of the third sub-encapsulation layer TFE3 and the bottom surface BS, and the angle between the fourth end E4 of the fourth sub-encapsulation layer TFE4 and the bottom surface BS may be equal to each other. In such embodiments, the aforementioned angle may be an acute angle.

Thereafter, the mask pattern MP may be removed by a strip process after the dry etching process.

Next, as illustrated in FIG. 7, the filling layer FIL may be formed on the plurality of lenses LNS, and the cover layer CVL may be arranged on the filling layer FIL. The cover layer CVL may be a glass substrate or a polymer resin. When the cover layer CVL is a glass substrate, it may serve as an encapsulation substrate, and the filling layer FIL may serve to adhere the cover layer CVL. When the cover layer CVL is a polymer resin, it may be directly applied onto the filling layer FIL.

Next, as illustrated in FIG. 7, the polarizing plate POL may be attached onto the cover layer CVL.

According to the method for fabricating the display device of one or more embodiments, the first sub-encapsulation layer TFE1, the third sub-encapsulation layer TFE3, and the fourth sub-encapsulation layer TFE4 may be patterned together in the process of exposing the first pad PD1 and the second pad PD2, so that the number of masks may be reduced. For example, the process of patterning the first sub-encapsulation layer TFE1, the third sub-encapsulation layer TFE3, and the fourth sub-encapsulation layer TFE4 and the process of exposing the second sub-pad metal layer SPML2 of each of the first pad PD1 and the second pad PD2 may be performed by one mask, e.g., the same mask (e.g., the mask pattern MP). Accordingly, the fabrication cost of the display device may be reduced.

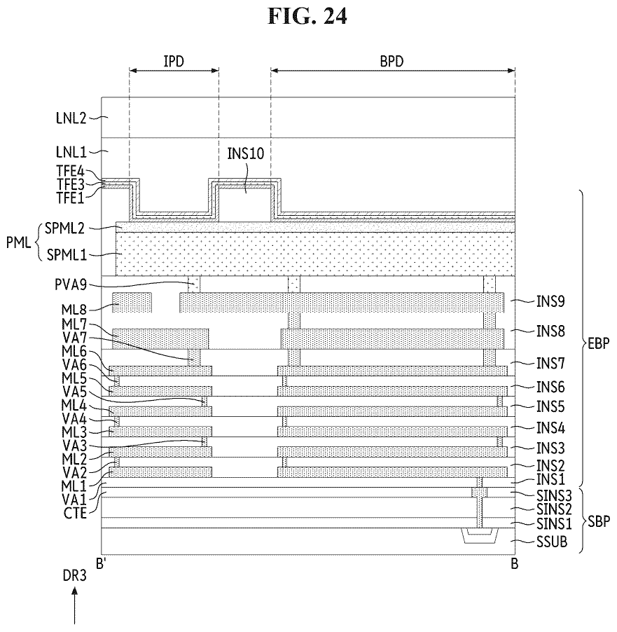

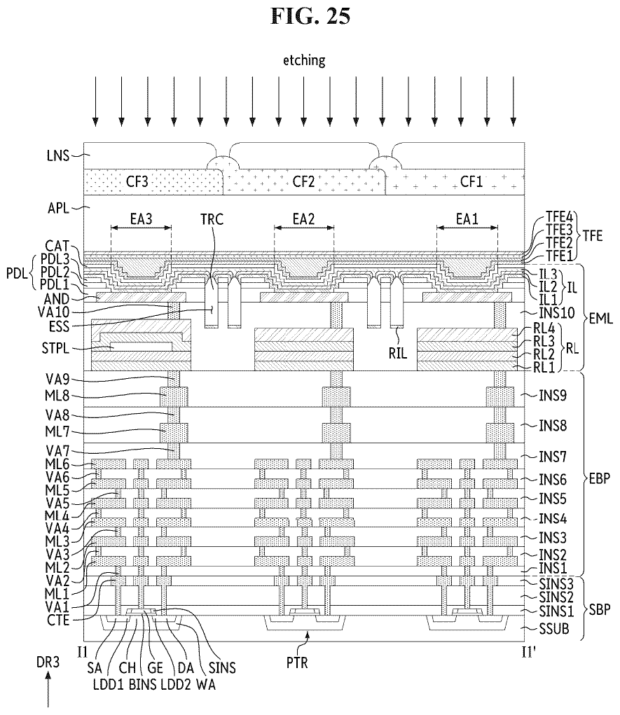

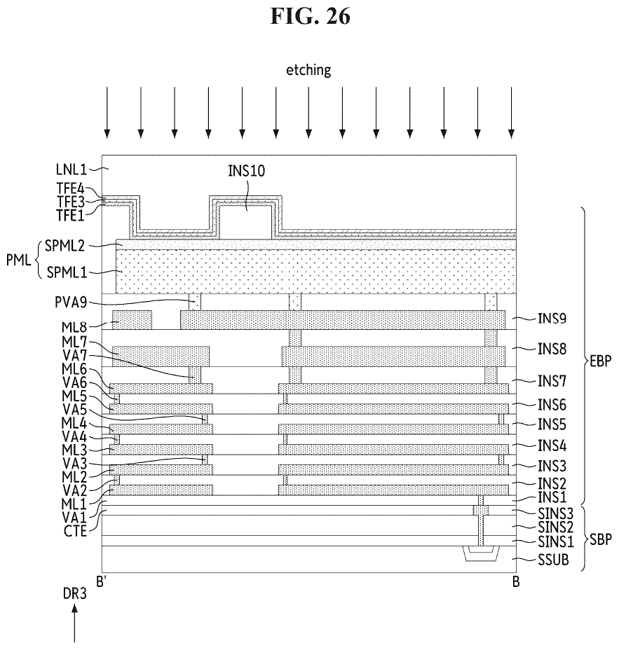

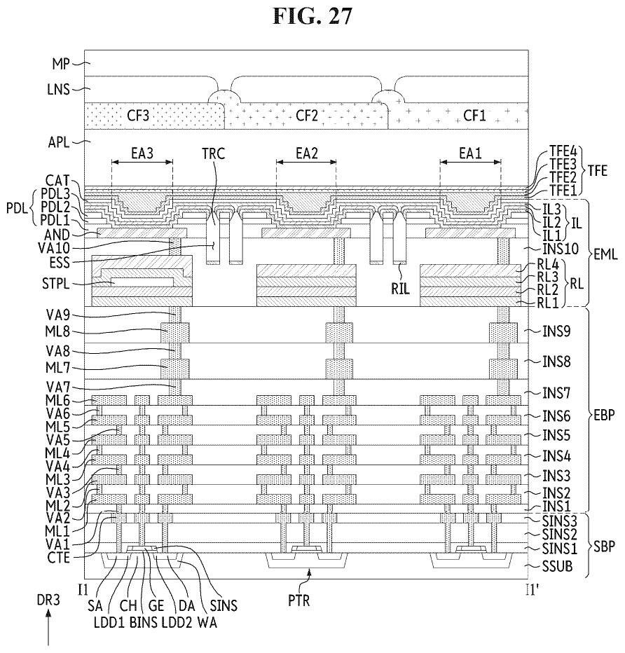

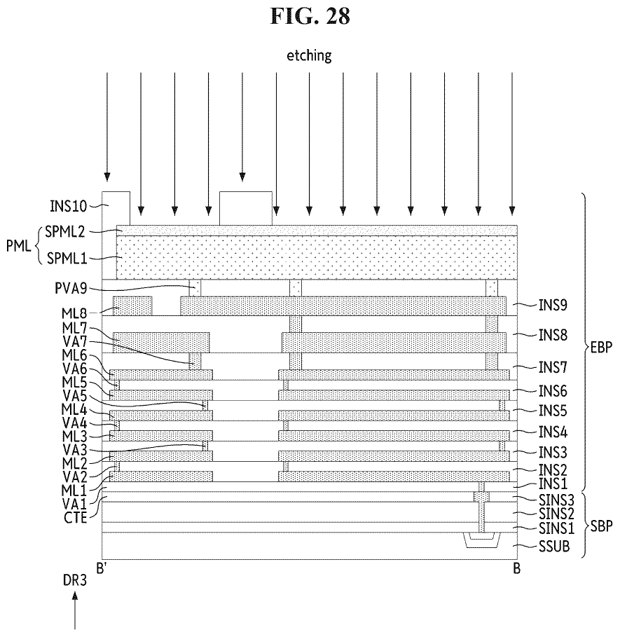

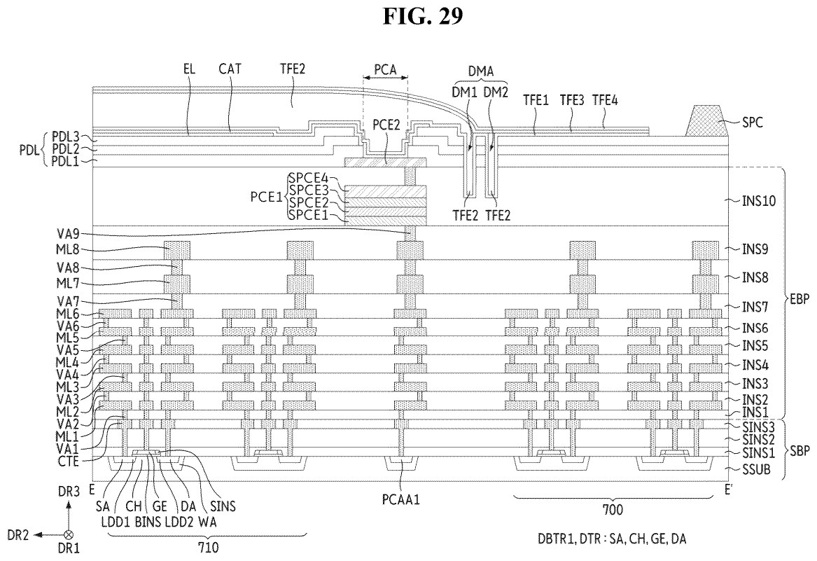

FIG. 29 is a cross-sectional view of a display device according to one or more embodiments. For example, FIG. 29 is a cross-sectional view showing another example of a display panel taken along the line E-E′ of FIG. 4, according to one or more embodiments of the present disclosure.

The display device of FIG. 29 differs from the display device of FIG. 11 in that it further includes a spacer SPC. The following description will mainly focus on this difference.

As shown in FIG. 29, the spacer SPC may be arranged on the third pixel-defining film PDL3. The spacer SPC may include an organic material. The spacer may support, e.g., a deposition mask used in a process of forming the second sub-encapsulation layer TFE2 described above. Accordingly, the contact between the deposition mask and the substrate structure (e.g., the third pixel-defining film PDL3) may be minimized or reduced during the process of forming the second sub-encapsulation layer TFE2. Hence, the generation of particles due to the contact between the deposition mask and the substrate structure and the contamination during the process by the particles may be prevented or reduced, thereby improving the reliability of the display device.

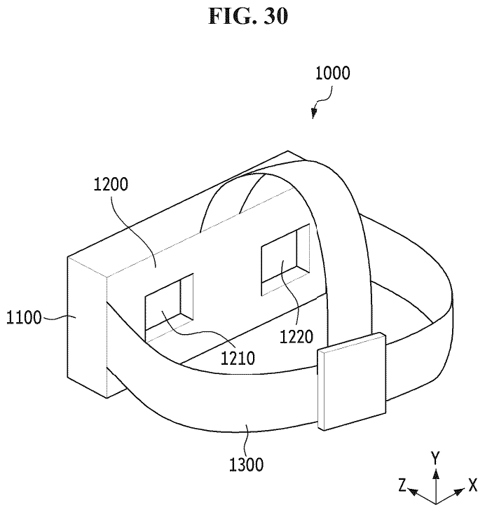

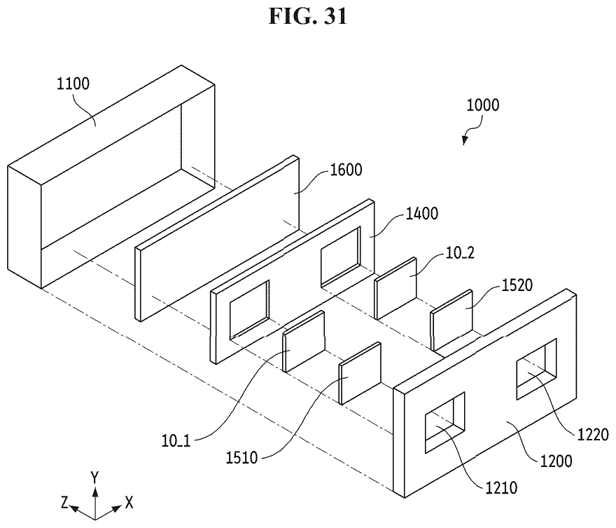

FIG. 30 is a perspective view illustrating a head-mounted display according to one or more embodiments of the present disclosure. FIG. 31 is an exploded perspective view illustrating the head mounted display of FIG. 30, according to one or more embodiments of the present disclosure.

Referring to FIGS. 30 and 31, a head-mounted display 1000 according to one or more embodiments includes a first display device 10_1, a second display device 10_2, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIGS. 1 to 29, redundant description of the first display device 10_1 and the second display device 10_2 may not be provided.

The first optical member 1510 may be arranged between the first display device 10_1 and the first eyepiece 1210. The second optical member 1520 may be arranged between the second display device 10_2 and the second eyepiece 1220.

Each of the first optical member 1510 and the second optical member 1520 may include at least one convex lens.

The middle frame 1400 may be arranged between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be arranged between the middle frame 1400 and the display device housing 1100. The control circuit board 1600 may be connected to the first display device 10_1 and the second display device 10_2 through the middle frame 1400. The control circuit board 1600 may convert an image source inputted from the outside into the digital video data DATA, and transmit the digital video data DATA to the first display device 10_1 and the second display device 10_2 through the middle frame 1400.

The control circuit board 1600 may be to transmit the digital video data DATA corresponding to a left-eye image that may be improved or optimized for the user's left eye to the first display device 10_1, and may be to transmit the digital video data DATA corresponding to a right-eye image that may be improved or optimized for the user's right eye to the second display device 10_2. Alternatively, in one or more embodiments, the control circuit board 1600 may be to transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is arranged to cover one open surface of the display device housing 1100. The housing cover 1200 may include the first eyepiece 1210 at which the user's left eye is located and the second eyepiece 1220 at which the user's right eye is located. FIGS. 30 and 31 illustrate that the first eyepiece 1210 and the second eyepiece 1220 are arranged separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

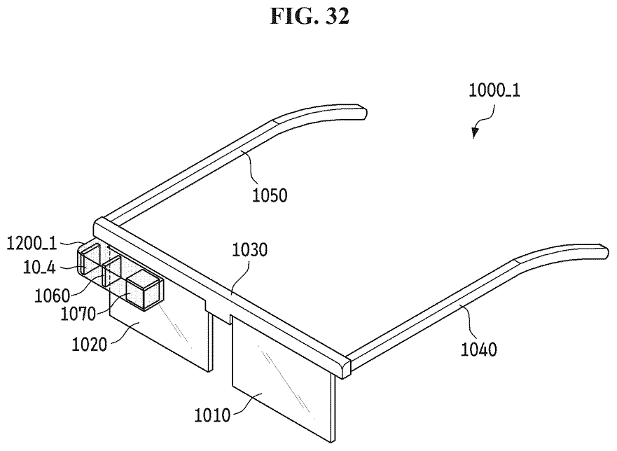

The head-mounted band 1300 serves to secure the display device housing 1100 to the user's head such that the first eyepiece 1210 and the second eyepiece 1220 of the housing cover 1200 remain located at (on) the user's left and right eyes, respectively. When the display device housing 1200 is implemented to be lightweight and compact, the head mounted display 1000 may be provided with an eyeglass frame as shown in FIG. 32 instead of the head mounted band 1300.

In one or more embodiments, the head-mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 32 is a perspective view illustrating a head-mounted display according to one or more embodiments of the present disclosure.

Referring to FIG. 32, a head-mounted display 1000_1 according to one or more embodiments may be an eyeglasses-type (kind) display device in which a display device housing 1200_1 is implemented in a lightweight and compact manner. The head-mounted display 1000_1 according to one or more embodiments may include a display device 10_4, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_4, the optical member 1060, and the optical path changing member 1070. The image displayed on the display device 10_4 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_4 and a real image seen through the right eye lens 1020 are combined.

FIG. 32 illustrates that the display device housing 1200_1 is arranged at the right end of the support frame 1030, but the present disclosure is not limited thereto. For example, the display device housing 1200_1 may be arranged at the left end of the support frame 1030, and in such embodiments, the image of the display device 10_4 may be provided to the user's left eye. Alternatively, in one or more embodiments, the display device housing 1200_1 may be arranged at both the left and right ends of the support frame 1030, and in such embodiments, the user may view the image displayed on the display device 10_4 through both (e.g., simultaneously) the left and right eyes.

The display device according to one or more embodiments can be applied to one or more suitable electronic devices. The electronic device according to one or more embodiments includes the display device described above and may further include modules or devices having additional functions in addition to the display device.

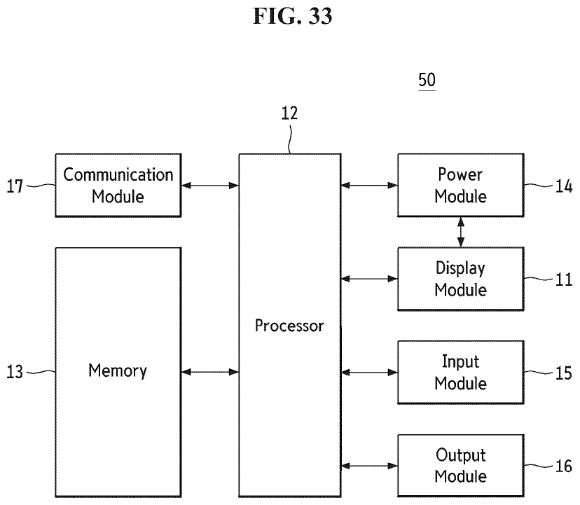

FIG. 33 is a block diagram of an electronic device according to one or more embodiments of the present disclosure. Referring to FIG. 33, the electronic device 50 according to one or more embodiments may include a display module 11, a processor 12, a memory 13, and a power module 14. The electronic device 50 may further include an input module 15, a non-image output module 16 and/or a communication module 17.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power for the operation of the electronic device 50. The input module 15 may provide input information to the processor 12 and/or the display module 11. The non-image output module 16 may receive information other than images transmitted from the processor 12, such as sound, haptics, and light, and provide the information to the user. The communication module 17 is a module that is responsible for transmitting and receiving information between the electronic device 50 and an external device, and may include a receiving unit and a transmitting unit.

At least one of the components of the electronic device 50 described above may be included in the display device according to one or more embodiments described above. In addition, some of the individual modules functionally included in one module may be included in the display device, and others may be provided separately from the display device. For example, the display module 11, and the processor 12, memory 13, and power module 14 may be provided in the form of other devices within the electronic device 50 other than the display device.

FIGS. 34, 35, and 36 are schematic diagrams of electronic devices according to one or more embodiments of the present disclosure. FIGS. 11 to 13 illustrate examples of one or more suitable electronic devices to which the display device according to one or more embodiments may be applied.

FIG. 34 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some embodiments.

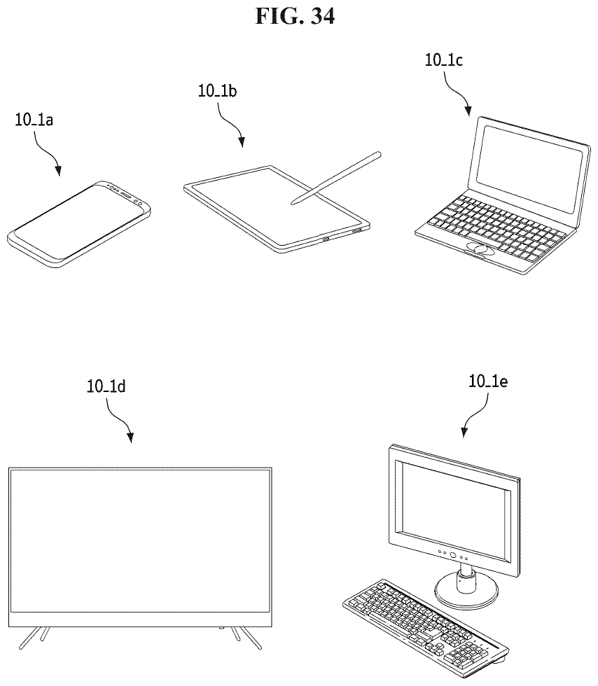

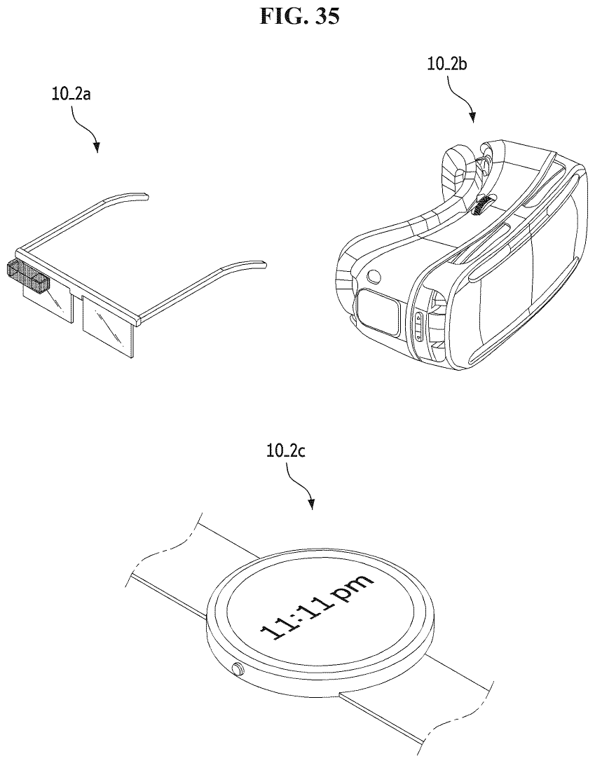

FIG. 35 shows an example of an electronic device including a display module being applied to a wearable electronic device. The wearable electronic device may be a smart glasses 10_2a, a head-mounted display 10_2b, a smart watch 10_2c, and/or the like.

The smart glasses 10_2a and the head-mounted display 10_2b may include a display module that emits a display image and a reflector that reflects the emitted display screen and provides it to the user's eyes, thereby providing a virtual reality and/or augmented reality screen to the user.

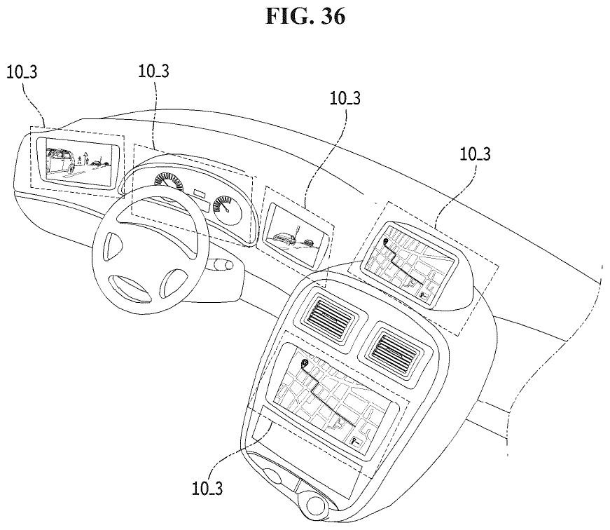

The smart watch 10_2c may include a biometric sensor as an input device, and may provide biometric information recognized by the biometric sensor to the user through the display module. FIG. 36 illustrates a case where an electronic device including a display module is applied to a vehicle. For example, the electronic device 10_3 may be applied to a dashboard, center fascia, and/or the like of a vehicle, or may be applied to a CID (Center Information Display) placed on a dashboard of a vehicle, or a room mirror display replacing a side mirror.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.” As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a first electrode on the substrate;
a pixel-defining film on the first electrode;
a light-emitting stack on the first electrode and the pixel-defining film;
a second electrode on the light-emitting stack; and
an encapsulation layer on the second electrode,
wherein the encapsulating layer comprises a plurality of sub-encapsulation layers, and
at least two ends of the plurality of sub-encapsulation layers are aligned along one direction.

2. The display device of claim 1, wherein the one direction is a diagonal direction.

3. The display device of claim 1, wherein an angle between the at least two ends of the plurality of sub-encapsulation layers and a bottom surface of one of the sub-encapsulation layers is an acute angle.

4. The display device of claim 3, wherein an angle between one of the at least two ends and the bottom surface is equal to an angle between another of the at least two ends and the bottom surface.

5. The display device of claim 1, wherein the encapsulating layer comprises:
a first sub-encapsulation layer on the pixel-defining film;
a second sub-encapsulation layer on the first sub-encapsulation layer;
a third sub-encapsulation layer on the second sub-encapsulation layer; and
a fourth sub-encapsulation layer on the third sub-encapsulation layer,
wherein the first sub-encapsulation layer, the third sub-encapsulation layer, and the fourth sub-encapsulation layer comprise an inorganic material, and
the second sub-encapsulation layer comprises an organic material.

6. The display device of claim 5, wherein respective ends of the first sub-encapsulation layer, the third sub-encapsulation layer, and the fourth sub-encapsulation layer are aligned along one direction.

7. The display device of claim 5, wherein respective ends of the first sub-encapsulation layer, the third sub-encapsulation layer, and the fourth sub-encapsulation layer are aligned along a diagonal direction.

8. The display device of claim 5, wherein an angle between an end of each of the first sub-encapsulation layer, the third sub-encapsulation layer, and the fourth sub-encapsulation layer and a bottom surface of the first sub-encapsulation layer is an acute angle.

9. The display device of claim 8, wherein an angle between the end of the first sub-encapsulation layer and the bottom surface, an angle between the end of the third sub-encapsulation layer and the bottom surface, and an angle between the end of the fourth sub-encapsulation layer and the bottom surface are equal to each other.

10. The display device of claim 1, further comprising an organic layer on the pixel-defining film.

11. An optical device comprising:
a display device; and
an optical path changing member on the display device,
wherein the display device comprises:
a substrate;
a first electrode on the substrate;
a pixel-defining film on the first electrode;
a light-emitting stack on the first electrode and the pixel-defining film;
a second electrode on the light-emitting stack; and
an encapsulation layer on the second electrode,
wherein the encapsulating layer comprises a plurality of sub-encapsulation layers, and
at least two ends of the plurality of sub-encapsulation layers are aligned along one direction.

12. The optical device of claim 11, wherein the at least two ends of the plurality of sub-encapsulation layers are aligned along a diagonal direction.

13. The optical device of claim 11, wherein an angle between the at least two ends of the plurality of sub-encapsulation layers and a bottom surface of one of the sub-encapsulation layers is an acute angle.

14. The optical device of claim 13, wherein an angle between one of the at least two ends and the bottom surface is equal to an angle between another of the at least two ends and the bottom surface..

15. The optical device of claim 11, wherein the encapsulating layer comprises:
a first sub-encapsulation layer on the pixel-defining film;
a second sub-encapsulation layer on the first sub-encapsulation layer;
a third sub-encapsulation layer on the second sub-encapsulation layer; and
a fourth sub-encapsulation layer on the third sub-encapsulation layer,
wherein the first sub-encapsulation layer, the third sub-encapsulation layer, and the fourth sub-encapsulation layer comprise an inorganic material, and
the second sub-encapsulation layer comprises an organic material.

16. The optical device of claim 15, wherein respective ends of the first sub-encapsulation layer, the third sub-encapsulation layer, and the fourth sub-encapsulation layer are aligned along one direction.

17. The optical device of claim 15, wherein respective ends of the first sub-encapsulation layer, the third sub-encapsulation layer, and the fourth sub-encapsulation layer are aligned along a diagonal direction.

18. The optical device of claim 15, wherein an angle between an end of each of the first sub-encapsulation layer, the third sub-encapsulation layer, and the fourth sub-encapsulation layer and a bottom surface of the first sub-encapsulation layer is an acute angle.

19. The optical device of claim 18, wherein an angle between the end of the first sub-encapsulation layer and the bottom surface, an angle between the end of the third sub-encapsulation layer and the bottom surface, and an angle between the end of the fourth sub-encapsulation layer and the bottom surface are equal to each other.

20. An electronic device comprising:
a display device comprising a screen,
wherein the display device comprises
a substrate;
a first electrode on the substrate;
a pixel-defining film on the first electrode;
a light-emitting stack on the first electrode and the pixel-defining film;
a second electrode on the light-emitting stack; and
an encapsulation layer on the second electrode,
wherein the encapsulating layer comprises a plurality of sub-encapsulation layers, and
at least two ends of the plurality of sub-encapsulation layers are aligned along one direction.
